(19) United States
(12) Patent Application Publication
(10) Pub. No.: US 2025/0331427 A1
(43) Pub. Date: Oct. 23, 2025

(54) MAGNETIC MEMORY DEVICE

(71) Applicant: SAMSUNG ELECTRONICS CO., LTD., Suwon-si (KR)

(72) Inventors: KILHO LEE, Suwon-si (KR); YONGJAE KIM, Suwon-si (KR)

(73) Assignee: SAMSUNG ELECTRONICS CO., LTD., Suwon-si (KR)

(21) Appl. No.: 19/056,096

(22) Filed: Feb. 18, 2025

(30) Foreign Application Priority Data
Apr. 17, 2024 (KR) 10-2024-0051659

(51) Int. Cl. H10N 50/10; G11C 11/16; H01F 10/32; H10B 61/00; H10N 50/85

(52) U.S. Cl. CPC H10N 50/10; G11C 11/161; G11C 11/1673; G11C 11/1675; H01F 10/3286; H10B 61/10; H10N 50/85

(57) ABSTRACT

A magnetic memory device is provided. The device includes: a first magnetic tunnel junction pattern on a first region of a substrate and a second magnetic tunnel junction pattern on a second region of the substrate. The first magnetic tunnel junction pattern includes a first fixed magnetic structure, a first free magnetic structure, and a first tunnel barrier pattern between the first fixed magnetic structure and the first free magnetic structure. The second magnetic tunnel junction pattern includes a second fixed magnetic structure, a second free magnetic structure, a second tunnel barrier pattern, and a multiferroic pattern. The second tunnel barrier pattern is between the second fixed magnetic structure and the second free magnetic structure. The second free magnetic structure is between the second tunnel barrier pattern and the multiferroic pattern. The multiferroic pattern has ferroelectricity and antiferromagnetism, and is selectively provided to the second magnetic tunnel junction pattern.

### CROSS-REFERENCE TO RELATED APPLICATION

This application claims priority under 35 U.S.C. § 119 to Korean Patent Application No. 10-2024-0051659, filed on Apr. 17, 2024, in the Korean Intellectual Property Office, the disclosure of which is incorporated by reference herein in its entirety.

### BACKGROUND

The present disclosure relates to a magnetic memory device with a magnetic tunnel junction, and a method for manufacturing the same.

To provide an electronic apparatus with increased speed and/or lower power consumption, there is an need for a semiconductor memory device which is faster and/or has a lower operating voltage. In order to satisfy such demands, a magnetic memory device has been proposed. The magnetic memory device may have characteristics such as high-speed operation and/or non-volatility, and thus is attracting attention as a next-generation semiconductor memory device.

The magnetic memory device may include a magnetic tunnel junction (MTJ) pattern. The magnetic tunnel junction pattern may include two magnetic bodies and an insulating film therebetween. A resistance value of the magnetic tunnel junction pattern may be changed depending on magnetization directions of the two magnetic bodies. For example, when the magnetization directions of the two magnetic bodies are antiparallel, the magnetic tunnel junction pattern may have a large resistance value, and when the magnetization directions of the two magnetic bodies are parallel, the magnetic tunnel junction pattern may have a small resistance value. Data may be written/read according to current resistance values.

As the electronics industry develops, various studies for providing, in a single chip, the magnetic tunnel junction patterns that function as memory elements respectively having different characteristics are being conducted.

### SUMMARY

One or more example embodiments provide a magnetic memory device including, in a single chip, magnetic tunnel junction patterns respectively having different operation characteristics.

One or more example embodiments also provide a method for manufacturing a magnetic memory device in which, in a single chip, magnetic tunnel junction patterns respectively having different operation characteristics.

According to an aspect of an example embodiment, a magnetic memory device includes: a substrate; a first magnetic tunnel junction pattern, on a first region of the substrate, the first magnetic tunnel junction pattern including a first fixed magnetic structure, a first free magnetic structure, and a first tunnel barrier pattern between the first fixed magnetic structure and the first free magnetic structure; and a second magnetic tunnel junction pattern on a second region of the substrate, the second magnetic tunnel junction pattern including a second fixed magnetic structure, a second free magnetic structure, a second tunnel barrier pattern, and a multiferroic pattern. The second tunnel barrier pattern is between the second fixed magnetic structure and the second free magnetic structure. The second free magnetic structure is between the second tunnel barrier pattern and the multiferroic pattern. The multiferroic pattern has ferroelectricity and antiferromagnetism, and is selectively provided to the second magnetic tunnel junction pattern.

According to another aspect of an example embodiment, a magnetic memory device includes: a substrate; a first magnetic tunnel junction pattern and a first electrode on a first region of the substrate; and a second magnetic tunnel junction pattern and second electrode on a second region of the substrate. The first magnetic tunnel junction pattern includes: a first fixed magnetic structure; a first tunnel barrier pattern between the first fixed magnetic structure and the first electrode; and a first free magnetic structure between the first tunnel barrier pattern and the first electrode. The second magnetic tunnel junction pattern includes: a second fixed magnetic structure; a second tunnel barrier pattern between the second fixed magnetic structure and the second electrode; a second free magnetic structure between the second tunnel barrier pattern and the second electrode; and a multiferroic pattern between the second free magnetic structure and the second electrode. The multiferroic pattern is offset from the first magnetic tunnel junction pattern.

According to another aspect of an example embodiment, a magnetic memory device including: a substrate; a first magnetic tunnel junction pattern, on a first region of the substrate, the first magnetic tunnel junction pattern including a first fixed magnetic structure, a first free magnetic structure, and a first tunnel barrier pattern between the first fixed magnetic structure and the first free magnetic structure; and a second magnetic tunnel junction pattern on a second region of the substrate, the second magnetic tunnel junction pattern including a second fixed magnetic structure, a second free magnetic structure, a second tunnel barrier pattern, and a multiferroic pattern. The second tunnel barrier pattern is between the second fixed magnetic structure and the second free magnetic structure. The second free magnetic structure is between the second tunnel barrier pattern and the multiferroic pattern. The multiferroic pattern has ferroelectricity and antiferromagnetism, and is offset from the first magnetic tunnel junction pattern.

### BRIEF DESCRIPTION OF DRAWINGS

The above and other aspects and features will be more apparent from the following description of example embodiments, taken in conjunction with the accompanying drawings, in which:

FIG. 1 is a plan view schematically illustrating a unit chip of a magnetic memory device according to example embodiments;

FIG. 2 is a circuit view illustrating a unit memory cell of a magnetic memory device according to example embodiments;

FIG. 3 is a cross-sectional view of a magnetic memory device according to some example embodiments;

FIG. 4 is a conceptual view illustrating characteristics of a multiferroic pattern of FIG. 3;

FIG. 5 is a conceptual view partially illustrating a second magnetic tunnel junction pattern during a reading operation of a magnetic memory device according to some example embodiments;

FIG. 6 is a conceptual view partially illustrating a second magnetic tunnel junction pattern during a writing operation of a magnetic memory device according to some example embodiments;

FIGS. 7 to 9 are cross-sectional views illustrating a method for manufacturing a magnetic memory device according to some example embodiments;

FIG. 10 is a cross-sectional view of a magnetic memory device according to some example embodiments;

FIGS. 11 and 12 are cross-sectional views illustrating a method for manufacturing a magnetic memory device according to some example embodiments;

FIG. 13 is a cross-sectional view of a magnetic memory device according to some example embodiments;

FIG. 14 is a cross-sectional view illustrating a method for manufacturing a magnetic memory device according to some example embodiments;

FIG. 15 is a cross-sectional view of a magnetic memory device according to some example embodiments;

FIGS. 16 to 18 are cross-sectional views illustrating a method for manufacturing a magnetic memory device according to some example embodiments;

FIG. 19 is a cross-sectional view of a magnetic memory device according to some example embodiments;

FIGS. 20 and 21 are cross-sectional views illustrating a method for manufacturing a magnetic memory device according to some example embodiments;

FIG. 22 is a cross-sectional view of a magnetic memory device according to some example embodiments;

FIG. 23 is a cross-sectional view illustrating a method for manufacturing a magnetic memory device according to some example embodiments;

FIG. 24 is a cross-sectional view of a magnetic memory device according to some example embodiments;

FIG. 25 is a conceptual view illustrating characteristics of a multiferroic pattern according to some example embodiments;

FIG. 26 is a conceptual view partially illustrating a second magnetic tunnel junction pattern during a reading operation of a magnetic memory device according to some example embodiments;

FIG. 27 is a conceptual view partially illustrating a second magnetic tunnel junction pattern during a writing operation of a magnetic memory device according to some example embodiments; and

FIG. 28 is a cross-sectional view of a magnetic memory device according to some example embodiments.

### DETAILED DESCRIPTION

Hereinafter, example embodiments are described in detail with reference to the accompanying drawings. Like components are denoted by like reference numerals throughout the specification, and repeated descriptions thereof are omitted. It will be understood that when an element or layer is referred to as being “on,” “connected to” or “coupled to” another element or layer, it can be directly on, connected or coupled to the other element or layer, or intervening elements or layers may be present. By contrast, when an element is referred to as being “directly on,” “directly connected to” or “directly coupled to” another element or layer, there are no intervening elements or layers present. Expressions such as “at least one from among,” and “at least one of,” when preceding a list of elements, modify the entire list of elements and do not modify the individual elements of the list. For example, the expression, “at least one from among a, b, and c,” should be understood as including only a, only b, only c, both a and b, both a and c, both b and c, or all of a, b, and c. Embodiments described herein are example embodiments, and thus, the present disclosure is not limited thereto, and may be realized in various other forms. Each example embodiment provided in the following description is not excluded from being associated with one or more features of another example or another embodiment also provided herein or not provided herein but consistent with the present disclosure.

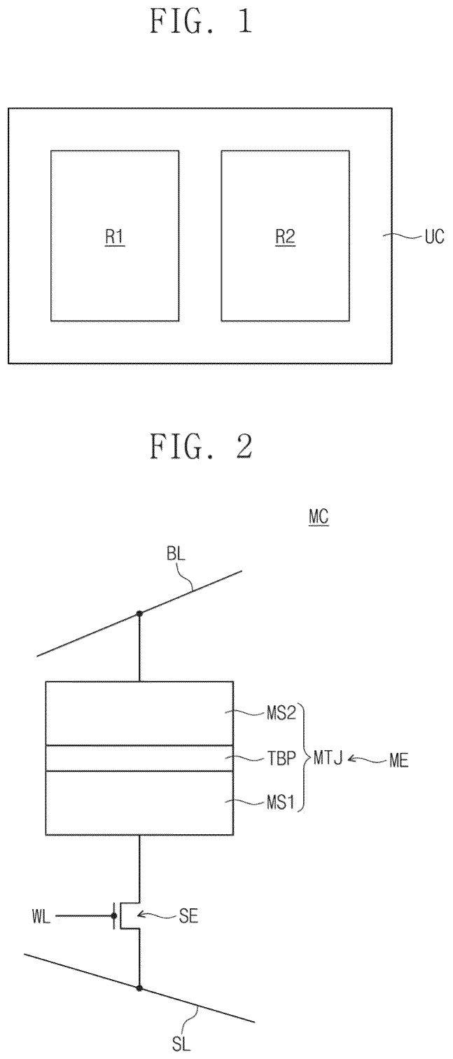

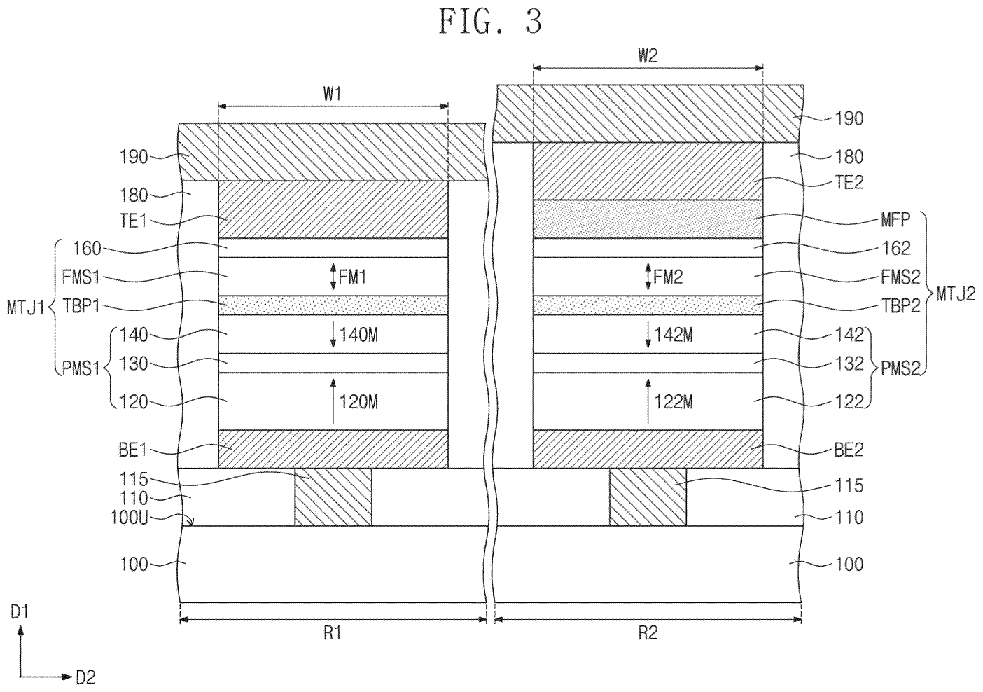

FIG. 1 is a plan view schematically illustrating a unit chip of a magnetic memory device according to example embodiments. FIG. 2 is a circuit view illustrating a unit memory cell of the magnetic memory device according to example embodiments.

Referring to FIG. 1, a unit chip UC may be a single chip including a first region R1 and a second region R2 different from each other. The first region R1 may be a region in which first memory cells are disposed, and the second region R2 may be a region in which second memory cells are disposed. The first memory cells may have different operation characteristics from the second memory cells. For example, the first memory cells may have a high switching speed, and the second memory cells may have high retention characteristics. The first memory cells may function as random access memory cells, and the second memory cells may function as non-volatile memory cells.

Referring to FIG. 2, each of the first and second memory cells MC may include a memory element ME and a selective element SE. The memory element ME and the selective element SE may be electrically connected to each other in series. The memory element ME may be connected between a bit line BL and the selective element SE. The selective element SE may be connected between the memory element ME and a source line SL, and may be controlled by a word line WL. For example, the selective element SE may include a field effect transistor.

The memory element ME may include a magnetic tunnel junction (MTJ) pattern, and the magnetic tunnel junction MTJ pattern may include a first magnetic structure MS1, a second magnetic structure MS2, and a tunnel barrier pattern TBP between the first and second magnetic structures MS1 and MS2. One of the first and second magnetic structures MS1 and MS2 may be a fixed magnetic structure in which a magnetization direction is fixed in one direction. The other of the first and second magnetic structures MS1 and MS2 may be a free magnetic structure in which a magnetization direction may be changed. An electrical resistance of the magnetic tunnel junction MTJ pattern may be much greater in a case in which the magnetization directions of the fixed magnetic structure and the free magnetic structure are antiparallel to each other than in a case in which the magnetization directions of the fixed magnetic structure and the free magnetic structure are parallel to each other. That is, the electrical resistance of the magnetic tunnel junction MTJ pattern may be controlled by changing the magnetization direction of the free magnetic structure parallel or antiparallel to the magnetization direction of the fixed magnetic structure. The memory element ME may store data in the unit memory cell MC by controlling the electrical resistance of the magnetic tunnel junction MTJ pattern (i.e., by controlling the magnetization direction of the free magnetic structure).

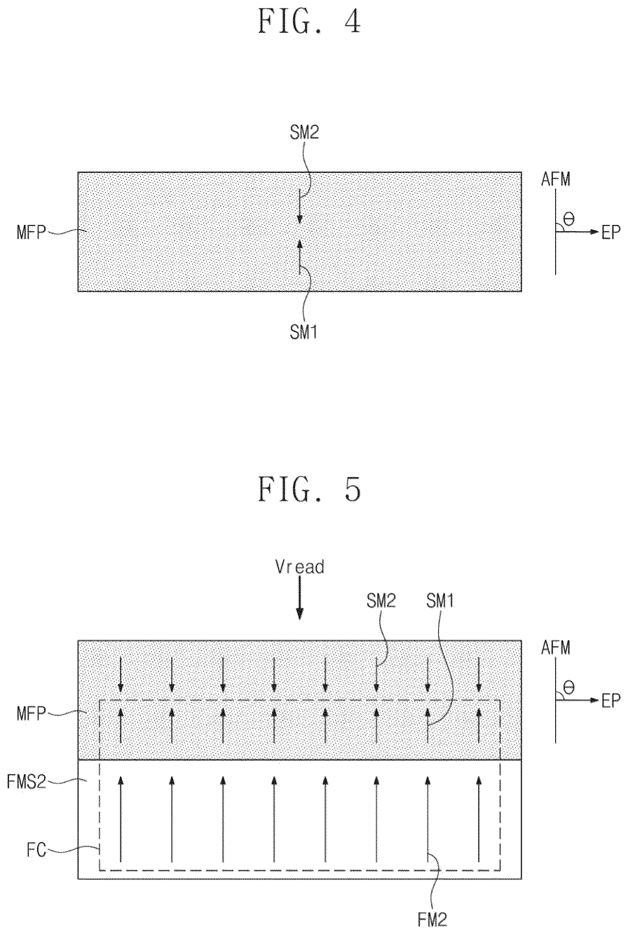

FIG. 3 is a cross-sectional view of a magnetic memory device according to some example embodiments, and FIG. 4 is a conceptual view illustrating characteristics of a multiferroic pattern of FIG. 3.

Referring to FIG. 3, a substrate 100 including a first region R1 and a second region R2 may be provided. The first region R1 and the second region R2 may be different regions of the substrate 100. The substrate 100 may be a semiconductor substrate including silicon (Si), silicon-on-insulator (SOI), silicon-germanium (SiGe), germanium (Ge), gallium arsenide (GaAs), or the like. Selective elements SE, which correspond to the selective element of FIG. 2, may be disposed on each of the first region R1 and the second region R2 of the substrate 100.

A lower insulating film 110 may be disposed on the substrate 100. The lower insulating film 110 may cover the first region R1 and the second region R2 of the substrate 100, and may cover the selective elements SE. For example, the lower insulating film 110 may include silicon oxide, silicon nitride, and/or silicon oxynitride.

Lower contact plugs 115 may be disposed on the first region R1 and the second region R2 of the substrate 100, and in the lower insulating film 110. Each of the lower contact plugs 115 may penetrate the lower insulating film 110, and may be electrically connected to corresponding one among the selective elements SE. For example, the selective elements SE may be field effect transistors, and each of the lower contact plugs 115 may be connected to one terminal (for example, a drain terminal) of a corresponding selective element. The lower contact plugs 115 may include at least one of a doped semiconductor material (for example, doped silicon), metal (for example, tungsten, titanium, and/or tantalum), a metal-semiconductor compound (for example, metal silicide), or conductive metal nitride (for example, titanium nitride, tantalum nitride, and/or tungsten nitride).

A first lower electrode BE1, a first magnetic tunnel junction pattern MTJ1, and a first upper electrode TE1 may be disposed on the first region R1 of the substrate 100, and may be sequentially stacked on a corresponding lower contact plug 115 along a first direction D1 perpendicular to an upper surface 100U of the substrate 100. The first lower electrode BE1 may be disposed between the corresponding lower contact plug 115 and the first magnetic tunnel junction pattern MTJ1, and the first magnetic tunnel junction pattern MTJ1 may be disposed between the first lower electrode BE1 and the first upper electrode TE1. The first lower electrode BE1 may be electrically connected to the corresponding lower contact plug 115. For example, the first lower electrode BE1 may include a conductive metal nitride (for example, titanium nitride or tantalum nitride). The first upper electrode TE1 may include at least one of metal (for example, Ta, W, Ru, Ir, or the like), or conductive metal nitride (for example, TiN).

The first magnetic tunnel junction pattern MTJ1 may include a first fixed magnetic structure PMS1, a first free magnetic structure FMS1, and a first tunnel barrier pattern TBP1 therebetween. According to some example embodiments, the first fixed magnetic structure PMS1 may be disposed between the first lower electrode BE1 and the first tunnel barrier pattern TBP1, and the first free magnetic structure FMS1 may be disposed between the first tunnel barrier pattern TBP1 and the first upper electrode TE1.

The first fixed magnetic structure PMS1 may include a first magnetic pattern 120, a second magnetic pattern 140, and a first exchange coupling pattern 130 therebetween. The first magnetic pattern 120 may be disposed between the first lower electrode BE1 and the first exchange coupling pattern 130, and the second magnetic pattern 140 may be disposed between the first exchange coupling pattern 130 and the first tunnel barrier pattern TBP1.

The first magnetic pattern 120 and the second magnetic pattern 140 may be antiferromagnetically coupled to each other by the first exchange coupling pattern 130, and thus a magnetization direction 140M of the second magnetic pattern 140 may be antiparallel to a magnetization direction 120M of the first magnetic pattern 120. The first fixed magnetic structure PMS1 may have a synthetic antiferromagnetic (SAF) structure.

The first fixed magnetic structure PMS1 may have perpendicular magnetic anisotropy. The magnetization directions 120M and 140M of the first and second magnetic patterns 120 and 140 may be perpendicular to an interface between the first tunnel barrier pattern TBP1 and the first free magnetic structure FMS1 (or an interface between the first tunnel barrier pattern TBP1 and the first fixed magnetic structure PMS1). For example, the magnetization directions 120M and 140M of the first and second magnetic patterns 120 and 140 may be perpendicular to the upper surface 100U of the substrate 100.

The first magnetic pattern 120 may include at least one of iron (Fe), cobalt (Co), or nickel (Ni). For example, the first magnetic pattern 120 may include at least one of a perpendicular magnetic material (for example, CoFeTb, CoFeGd, CoFeDy), a perpendicular magnetic material having an L1₀ structure, CoPt having a hexagonal closest packed lattice structure, or a perpendicular magnetic structure. The perpendicular magnetic material having an L1₀ structure may include at least one of FePt having an L1₀ structure, FePd having an L1₀ structure, CoPd having an L1₀ structure, CoPt having an L1₀ structure, or the like. The perpendicular magnetic structure may include magnetic layers and non-magnetic layers alternately and repeatedly stacked. For example, the perpendicular magnetic structure may include at least one of (Co/Pt)n, (CoFe/Pt)n, (CoFe/Pd)n, (Co/Pd)n, (Co/Ni)n, (CoNi/Pt)n, (CoCr/Pt)n, (CoCr/Pd)n (n is a number of stacks), or the like.

The second magnetic pattern 140 may include at least one of iron (Fe), cobalt (Co), or nickel (Ni). The first exchange coupling pattern 130 may include a non-magnetic material having antiferromagnetic coupling characteristics. For example, the first exchange coupling pattern 130 may include at least one of iridium (Ir) or ruthenium (Ru).

The first tunnel barrier pattern TBP1 may include metal oxide. For example, the first tunnel barrier pattern TBP1 may include at least one of magnesium (Mg) oxide, titanium (Ti) oxide, aluminum (Al) oxide, magnesium-zinc (Mg—Zn) oxide, or magnesium-boron (Mg—B) oxide.

The first free magnetic structure FMS1 may have perpendicular magnetic anisotropy derived by a junction of the first free magnetic structure FMS1 and the first tunnel barrier pattern TBP1. A magnetization direction FM1 of the first free magnetic structure FMS1 may be perpendicular to an interface between the first tunnel barrier pattern TBP1 and the first free magnetic structure FMS1 (or an interface between the first tunnel barrier pattern TBP1 and the first fixed magnetic structure PMS1). For example, a magnetization direction FM1 of the first free magnetic structure FMS1 may be perpendicular to the upper surface 100U of the substrate 100. The magnetization direction FM1 of the first free magnetic structure FMS1 may be changed to a direction parallel or antiparallel to the magnetization direction 140M of the second magnetic pattern 140. The first free magnetic structure FMS1 may include a magnetic material capable of deriving the perpendicular magnetic anisotropy on the interface between the first free magnetic structure FMS1 and the first tunnel barrier pattern TBP1, and may include, for example, cobalt-iron-boron (CoFeB).

The first magnetic tunnel junction pattern MTJ1 may further include a first non-magnetic pattern 160 between the first free magnetic structure FMS1 and the first upper electrode TE1. The first non-magnetic pattern 160 may prevent degradation of the first free magnetic structure FMS1. For example, the first non-magnetic pattern 160 may include at least one of tantalum (Ta), tungsten (W), iridium (Ir), ruthenium (Ru), molybdenum (Mo), aluminum (Al), copper (Cu), gold (Au), silver (Ag), titanium (Ti), tantalum nitride (TaN), or titanium nitride (TiN).

A second lower electrode BE2, a second magnetic tunnel junction pattern MTJ2, and a second upper electrode TE2 may be disposed on the second region R2 of the substrate 100, and may be sequentially stacked on a corresponding lower contact plug 115 along the first direction D1. The second lower electrode BE2 may be disposed between the corresponding lower contact plug 115 and the second magnetic tunnel junction pattern MTJ2, and the second magnetic tunnel junction pattern MTJ2 may be disposed between the second lower electrode BE2 and the second upper electrode TE2. The second lower electrode BE2 may be electrically connected to the corresponding lower contact plug 115. For example, the second lower electrode BE2 may include a conductive metal nitride (for example, titanium nitride or tantalum nitride). The second upper electrode TE2 may include at least one of metal (for example, Ta, W, Ru, Ir, or the like) or conductive metal nitride (for example, TiN). The first lower electrode BE1 and the second lower electrode BE2 may include the same material, and the first upper electrode TE1 and the second upper electrode TE2 may include the same material.

The second magnetic tunnel junction pattern MTJ2 may include a second fixed magnetic structure PMS2, a second free magnetic structure FMS2, and a second tunnel barrier pattern TBP2 therebetween. According to some example embodiments, the second fixed magnetic structure PMS2 may be disposed between the second lower electrode BE2 and the second tunnel barrier pattern TBP2, and the second free magnetic structure FMS2 may be disposed between the second tunnel barrier pattern TBP2 and the second upper electrode TE2.

The second fixed magnetic structure PMS2 may include a third magnetic pattern 122, a fourth magnetic pattern 142, and a second exchange coupling pattern 132 therebetween. According to some example embodiments, the third magnetic pattern 122 may be disposed between the second lower electrode BE2 and the second exchange coupling pattern 132, and the fourth magnetic pattern 142 may be disposed between the second exchange coupling pattern 132 and the second tunnel barrier pattern TBP2.

The third magnetic pattern 122 and the fourth magnetic pattern 142 may be antiferromagnetically coupled to each other by the second exchange coupling pattern 132, and thus a magnetization direction 142M of the fourth magnetic pattern 142 may be antiparallel to a magnetization direction 122M of the third magnetic pattern 122. The second fixed magnetic structure PMS2 may have a synthetic antiferromagnetic (SAF) structure.

The second fixed magnetic structure PMS2 may have perpendicular magnetic anisotropy. The magnetization directions 122M and 142M of the third and fourth magnetic patterns 122 and 142 may be perpendicular to an interface between the second tunnel barrier pattern TBP2 and the second free magnetic structure FMS2 (or an interface between the second tunnel barrier pattern TBP2 and the second fixed magnetic structure PMS2). For example, the magnetization directions 122M and 142M of the third and fourth magnetic patterns 122 and 142 may be perpendicular to the upper surface 100U of the substrate 100.

The third magnetic pattern 122 may include at least one of iron (Fe), cobalt (Co), or nickel (Ni). For example, the third magnetic pattern 122 may include at least one of a perpendicular magnetic material (for example, CoFeTb, CoFeGd, CoFeDy), a perpendicular magnetic material having an L1₀ structure, CoPt having a hexagonal closest packed lattice structure, or a perpendicular magnetic structure. The perpendicular magnetic material having an L1₀ structure may include at least one of FePt having an L1₀ structure, FePd having an L1₀ structure, CoPd having an L1₀ structure, CoPt having an L1₀ structure, or the like. The perpendicular magnetic structure may include magnetic layers and non-magnetic layers alternately and repeatedly stacked. For example, the perpendicular magnetic structure may include at least one of (Co/Pt)n, (CoFe/Pt)n, (CoFe/Pd)n, (Co/Pd)n, (Co/Ni)n, (CoNi/Pt)n, (CoCr/Pt)n, (CoCr/Pd)n (n is a number of stacks), or the like.

The fourth magnetic pattern 142 may include at least one of iron (Fe), cobalt (Co), or nickel (Ni). The second exchange coupling pattern 132 may include a non-magnetic material having antiferromagnetic coupling characteristics. For example, the second exchange coupling pattern 132 may include at least one of iridium (Ir) or ruthenium (Ru).

The first fixed magnetic structure PMS1 and the second fixed magnetic structure PMS2 may include the same material. The first magnetic pattern 120 and the third magnetic pattern 122 may include the same material, and the second magnetic pattern 140 and the fourth magnetic pattern 142 may include the same material. The first exchange coupling pattern 130 and the second exchange coupling pattern 132 may include the same material.

The second tunnel barrier pattern TBP2 may include metal oxide. For example, the second tunnel barrier pattern TBP2 may include at least one of magnesium (Mg) oxide, titanium (Ti) oxide, aluminum (Al) oxide, magnesium-zinc (Mg—Zn) oxide, or magnesium-boron (Mg—B) oxide. The first tunnel barrier pattern TBP1 and the second tunnel barrier pattern TBP2 may include the same material.

The second free magnetic structure FMS2 may have perpendicular magnetic anisotropy derived by a junction of the second free magnetic structure FMS2 and the second tunnel barrier pattern TBP2. A magnetization direction FM2 of the second free magnetic structure FMS2 may be perpendicular to an interface between the second tunnel barrier pattern TBP2 and the second free magnetic structure FMS2 (or an interface between the second tunnel barrier pattern TBP2 and the second fixed magnetic structure PMS2). For example, the magnetization direction FM2 of the second free magnetic structure FMS2 may be perpendicular to the upper surface 100U of the substrate 100. The magnetization direction FM2 of the second free magnetic structure FMS2 may be changed to a direction parallel or antiparallel to the magnetization direction 142M of the fourth magnetic pattern 142. The second free magnetic structure FMS2 may include a magnetic material capable of deriving the perpendicular magnetic anisotropy on the interface between the second free magnetic structure FMS2 and the second tunnel barrier pattern TBP2, and may include, for example, cobalt-iron-boron (CoFeB). The first free magnetic structure FMS1 and the second free magnetic structure FMS2 may include the same material.

Referring to FIGS. 3 and 4, the second magnetic tunnel junction pattern MTJ2 may further include a multiferroic pattern MFP between the second free magnetic structure FMS2 and the second upper electrode TE2. The multiferroic pattern MFP may have ferroelectricity and antiferromagnetism.

The multiferroic pattern MFP may have electric polarization EP caused by ferroelectricity, and a direction of the electric polarization EP may be changed by an external electric field applied to the multiferroic pattern MFP. The multiferroic pattern MFP may have a first magnetic moment SM1 and a second magnetic moment SM2 aligned antiparallel to each other, and thus may have antiferromagnetism. The multiferroic pattern MFP may have an antiferromagnetic axis AFM indicating a direction in which the first and second magnetic moments SM1 and SM2 are aligned, and the antiferromagnetic axis AFM may be changed by an external magnetic field applied to the multiferroic pattern MFP. A direction of the electric polarization EP may have a predetermined angle θ with respect to the antiferromagnetic axis AFM. The angle θ may be changed depending on a material that constitutes the multiferroic pattern MFP. For example, the angle θ may be 0° to 90°. Due to a magnetoelectric effect of a multiferroics, a direction of the antiferromagnetic axis AFM may be changed by changing a direction of the electric polarization EP using the external electric field, and a direction of the electric polarization EP may be changed by changing a direction of the antiferromagnetic axis AFM using the external magnetic field.

The multiferroic pattern MFP may include a multiferroic oxide having a perovskite structure. For example, the multiferroic pattern MFP may include BiFeO₃, YMnO₃, PbTiO₃, BaTiO₃, or the like. When the multiferroic pattern MFP includes BiFeO₃, the angle θ between a direction of the electric polarization EP and the antiferromagnetic axis AFM may be about 90°. That is, the direction of the electric polarization EP and the antiferromagnetic axis AFM may be perpendicular to each other.

According to some example embodiments, the antiferromagnetic axis AFM of the multiferroic pattern MFP may be parallel to the magnetization direction FM2 of the second free magnetic structure FMS2. The antiferromagnetic axis AFM of the multiferroic pattern MFP and the magnetization direction FM2 of the second free magnetic structure FMS2 may be perpendicular to the upper surface 100U of the substrate 100. According to some example embodiments, the direction of the electric polarization EP of the multiferroic pattern MFP may be parallel to the upper surface 100U of the substrate 100.

Referring back to FIG. 3, the multiferroic pattern MFP may be selectively provided to the second magnetic tunnel junction pattern MTJ2, and the first magnetic tunnel junction pattern MTJ1 may not include the multiferroic pattern MFP.

The second magnetic tunnel junction pattern MTJ2 may further include a second non-magnetic pattern 162 between the second free magnetic structure FMS2 and the multiferroic pattern MFP. The second non-magnetic pattern 162 may prevent degradation of the second free magnetic structure FMS2, and may ferromagnetically couple the second free magnetic structure FMS2 and the multiferroic pattern MFP. For example, the second non-magnetic pattern 162 may include at least one of tantalum (Ta), tungsten (W), iridium (Ir), ruthenium (Ru), molybdenum (Mo), aluminum (Al), copper (Cu), gold (Au), silver (Ag), titanium (Ti), tantalum nitride (TaN), or titanium nitride (TiN). The first non-magnetic pattern 160 and the second non-magnetic pattern 162 may include the same material.

Each of the first and second magnetic tunnel junction patterns MTJ1 and MTJ2 may have a width (for example, the maximum width) along a second direction D2 parallel to the upper surface 100U of the substrate 100. Along the second direction D2, a first width W1 of the first magnetic tunnel junction pattern MTJ1 may be the same as a second width W2 of the second magnetic tunnel junction pattern MTJ2.

An upper insulating film 180 may be disposed on the lower insulating film 110 on the first and second regions R1 and R2 of the substrate 100. The upper insulating film 180 may cover side surfaces of the first lower electrode BE1, the first magnetic tunnel junction pattern MTJ1, and the first upper electrode TE1 on the first region R1. The upper insulating film 180 may cover side surfaces of the second lower electrode BE2, the second magnetic tunnel junction pattern MTJ2, and the second upper electrode TE2 on the second region R2. For example, the upper insulating film 180 may include silicon oxide, silicon nitride, and/or silicon oxynitride.

Upper lines 190 may be disposed on the upper insulating film 180 on the first and second regions R1 and R2 of the substrate 100. The first magnetic tunnel junction pattern MTJ1 may be electrically connected to corresponding one among the upper lines 190 through the first upper electrode TE1. The second magnetic tunnel junction pattern MTJ2 may be electrically connected to corresponding one among the upper lines 190 through the second upper electrode TE2. The upper lines 190 may include metal (for example, copper).

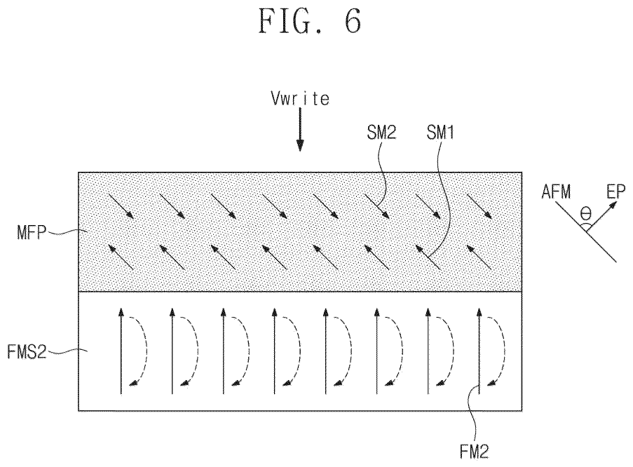

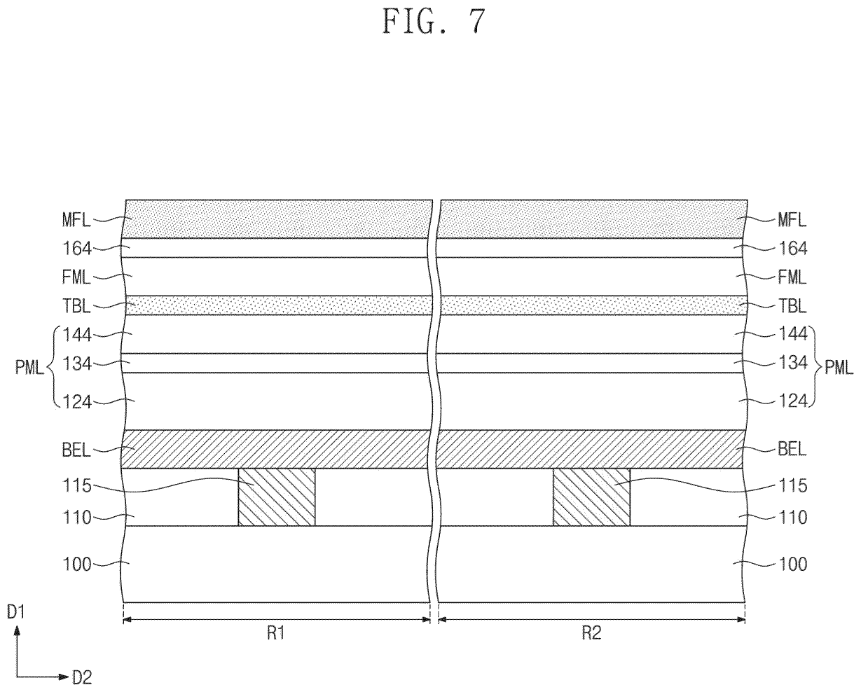

FIG. 5 is a conceptual view partially illustrating the second magnetic tunnel junction pattern of FIG. 3 during a reading operation of a magnetic memory device according to some example embodiments, and FIG. 6 is a conceptual view partially illustrating the second magnetic tunnel junction pattern of FIG. 3 during a writing operation of the magnetic memory device according to some example embodiments. In order to simplify illustration, the second non-magnetic pattern of FIG. 3 is omitted in FIGS. 5 and 6.

Referring to FIG. 5, the first magnetic moment SM1 may be ferromagnetically coupled to the magnetization direction FM2 of the second free magnetic structure FMS2 in a region of the multiferroic pattern MFP, adjacent to the second free magnetic structure FMS2. Because the multiferroic pattern MFP has antiferromagnetism, the second magnetic moment SM2 may be aligned antiparallel to the first magnetic moment SM1. The first and second magnetic moments SM1 and SM2 may be aligned parallel to the antiferromagnetic axis AFM, and the antiferromagnetic axis AFM may be parallel to the magnetization direction FM2 of the second free magnetic structure FMS2. For example, the antiferromagnetic axis AFM of the multiferroic pattern MFP and the magnetization direction FM2 of the second free magnetic structure FMS2 may be perpendicular to the upper surface 100U of the substrate 100.

A direction of the electric polarization EP of the multiferroic pattern MFP may have the angle θ with respect to the antiferromagnetic axis AFM. For example, when the multiferroic pattern MFP includes BiFeO₃, the direction of the electric polarization EP and the antiferromagnetic axis AFM may be perpendicular to each other. For example, the direction of the electric polarization EP may be parallel to the upper surface 100U of the substrate 100.

When a read voltage Vread is applied to the second magnetic tunnel junction pattern MTJ2, a first external electric field may be applied to the multiferroic pattern MFP by the read voltage Vread. The read voltage Vread may have a sufficiently small value such that the direction of the electric polarization EP of the multiferroic pattern MFP is not changed by the first external electric field, and may be, for example, equal to or less than about 0.05 V. In this case, the direction of the electric polarization EP of the multiferroic pattern MFP may not be switched by the read voltage Vread, and thus the antiferromagnetic axis AFM of the multiferroic pattern MFP may not be changed by the read voltage Vread.

Due to ferromagnetic coupling FC between the first magnetic moment SM1 of the multiferroic pattern MFP and the magnetization direction FM2 of the second free magnetic structure FMS2, thermal stability of the second free magnetic structure FMS2 may be increased, and the magnetization direction FM2 of the second free magnetic structure FMS2 may be prevented from being switched by the read voltage Vread.

Referring to FIG. 6, when a write voltage Vwrite is applied to the second magnetic tunnel junction pattern MTJ2, a second external electric field caused by the write voltage Vwrite may be applied to the multiferroic pattern MFP. The write voltage Vwrite may have a sufficiently large value such that the direction of the electric polarization EP of the multiferroic pattern MFP may be changed by the second external electric field, and may be, for example, greater than about 0.05 V. The write voltage Vwrite may be applied to switch the direction of the electric polarization EP of the multiferroic pattern MFP, and thus the antiferromagnetic axis AFM of the multiferroic pattern MFP may be changed by the write voltage Vwrite.

The antiferromagnetic axis AFM of the multiferroic pattern MFP may be inclined non-parallel to the magnetization direction FM2 of the second free magnetic structure FMS2. For example, the antiferromagnetic axis AFM of the multiferroic pattern MFP may be inclined non-perpendicular to the upper surface 100U of the substrate 100. The antiferromagnetic axis AFM of the multiferroic pattern MFP may be inclined non-parallel and non-perpendicular to the magnetization direction FM2 of the second free magnetic structure FMS2. For example, the antiferromagnetic axis AFM of the multiferroic pattern MFP may be inclined non-perpendicular and non-parallel to the upper surface 100U of the substrate 100.

Because the antiferromagnetic axis AFM of the multiferroic pattern MFP is inclined non-parallel to the magnetization direction FM2 of the second free magnetic structure FMS2, the ferromagnetic coupling FC between the first magnetic moment SM1 of the multiferroic pattern MFP and the magnetization direction FM2 of the second free magnetic structure FMS2 may be reduced. Accordingly, the magnetization direction FM2 of the second free magnetic structure FMS2 may be switched by the write voltage Vwrite.

According to example embodiments, the first magnetic tunnel junction pattern MTJ1 may not include the multiferroic pattern MFP, and the second magnetic tunnel junction pattern MTJ2 may include the multiferroic pattern MFP. The multiferroic pattern MFP may be selectively provided to the second magnetic tunnel junction pattern MTJ2. Because the second magnetic tunnel junction pattern MTJ2 includes the multiferroic pattern MFP, the second free magnetic structure FMS2 may have more thermal stability than the first free magnetic structure FMS1. Accordingly, the second magnetic tunnel junction pattern MTJ2 may have higher retention characteristics than the first magnetic tunnel junction pattern MTJ1, and the first magnetic tunnel junction pattern MTJ1 may have higher switching speed characteristics than the second magnetic tunnel junction pattern MTJ2. The first magnetic tunnel junction pattern MTJ1 may constitute a first memory cell (for example, a random access memory cell) having relatively high switching speed characteristics, and the second magnetic tunnel junction pattern MTJ2 may constitute a second memory cell (for example, a non-volatile memory cell) having relatively high retention characteristics.

Because the multiferroic pattern MFP is selectively provided to the second magnetic tunnel junction pattern MTJ2 of the first and second magnetic tunnel junction patterns MTJ1 and MTJ2 disposed on the single substrate 100, magnetic tunnel junction patterns having different operation characteristics may be provided on the single substrate 100. Accordingly, a magnetic memory device including the magnetic tunnel junction patterns having the different operation characteristics may be provided in a single chip.

FIGS. 7 to 9 are cross-sectional views illustrating a method for manufacturing a magnetic memory device according to some example embodiments. In order to simplify description, duplicated description of the magnetic memory device described with reference to FIGS. 1 to 6 will be omitted.

The selective element SE of FIG. 2 may be formed on each of a first region R1 and a second region R2 of a substrate 100. A lower insulating film 110 may be formed on the substrate 100. The lower insulating film 110 may cover the first region R1 and the second region R2 of the substrate 100, and may cover the selective elements SE.

Lower contact plugs 115 may be formed on the first region R1 and the second region R2 of the substrate 100, and in the lower insulating film 110. For example, a plurality of selective elements SE may be provided in the substrate 100, and each of the lower contact plugs 115 may correspond to one of the selective elements SE in the substrate 100. For example, an operation of forming the lower contact plugs 115 may include an operation of forming lower contact holes penetrating the lower insulating film 110, an operation of forming, on the lower insulating film 110, a lower contact film that fills the lower contact holes, and an operation of planarizing the lower contact film until an upper surface of the lower insulating film 110 is exposed.

A lower electrode film BEL, a fixed magnetic film PML, a tunnel barrier film TBL, a free magnetic film FML, a non-magnetic film 164, and a multiferroic film MFL may be formed on the first region R1 and the second region R2 of the substrate 100, and on the lower insulating film 110. The lower electrode film BEL, the fixed magnetic film PML the tunnel barrier film TBL, the free magnetic film FML, the non-magnetic film 164, and the multiferroic film MFL may be sequentially stacked on the lower insulating film 110 along the first direction D1. The fixed magnetic film PML may include a first magnetic film 124, an exchange coupling film 134, and a second magnetic film 144 sequentially stacked on the lower electrode film BEL along the first direction D1. The lower electrode film BEL, the fixed magnetic film PML, the tunnel barrier film TBL, the free magnetic film FML, the non-magnetic film 164, and the multiferroic film MFL may be formed in a chemical vapor deposition (CVD) process or a physical vapor deposition (PVD) process, and may be formed, for example, in a sputtering deposition process.

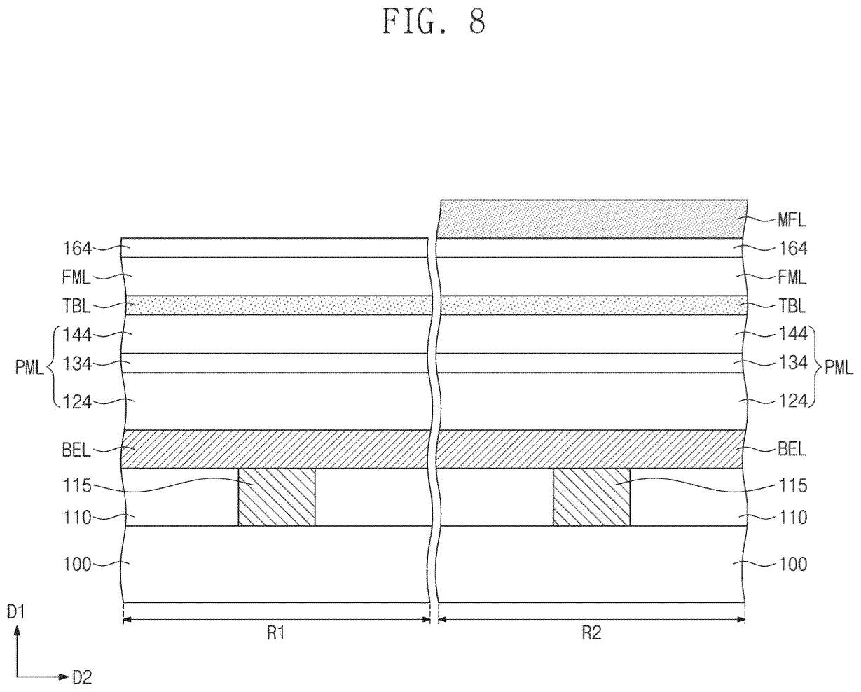

Referring to FIG. 8, the multiferroic film MFL on the first region R1 of the substrate 100 may be selectively removed. For example, an operation of selectively removing the multiferroic film MFL on the first region R1 may include an operation of forming a first mask pattern on the multiferroic film MFL on the second region R2, and an operation of etching the multiferroic film MFL on the first region R1 by using the first mask pattern as an etching mask. The first mask pattern may cover the multiferroic film MFL on the second region R2, and may expose the multiferroic film MFL on the first region R1. The operation of etching the multiferroic film MFL on the first region R1 may be performed until the non-magnetic film 164 on the first region R1 is exposed. After the multiferroic film MFL on the first region R1 is selectively removed, the first mask pattern may be removed. For example, the first mask pattern may be a photoresist pattern or hard mask pattern, and may be removed, for example, through an ashing and/or a strip process.

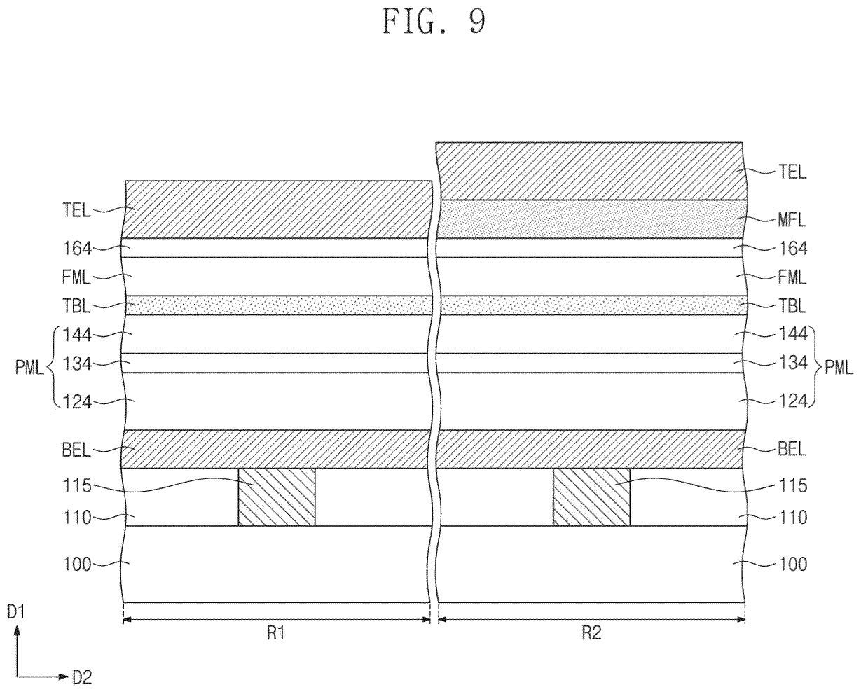

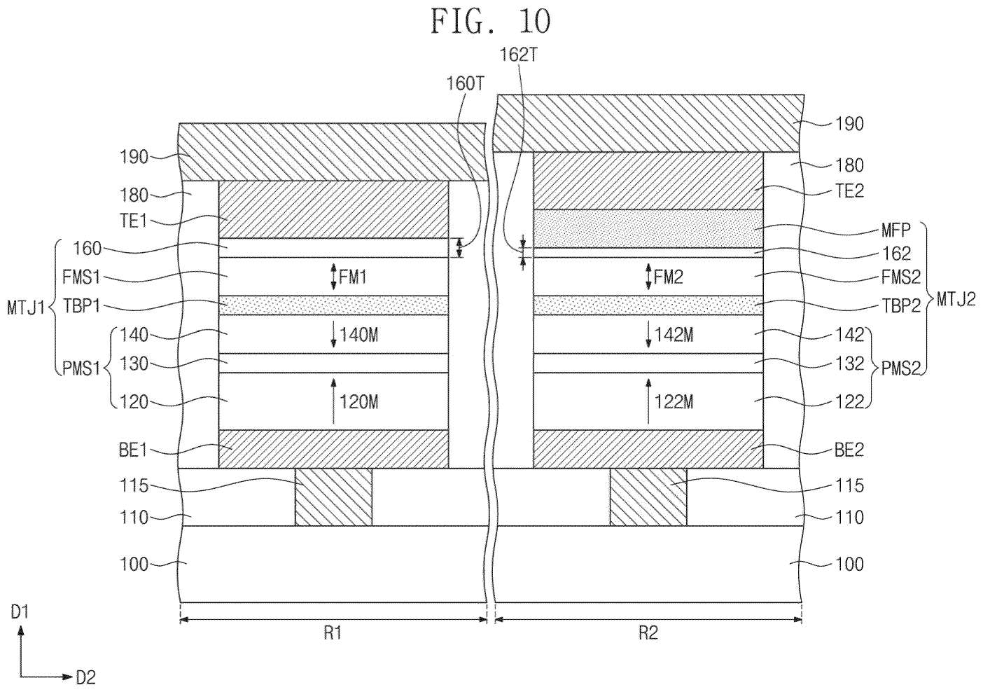

Referring to FIG. 9, an upper electrode film TEL may be formed on the first region R1 and the second region R2 of the substrate 100. The upper electrode film TEL may cover the non-magnetic film 164 on the first region R1 of the substrate 100, and may cover the multiferroic film MFL on the second region R2 of the substrate 100. The upper electrode film TEL may be formed in a chemical vapor deposition (CVD) process or a physical vapor deposition (PVD) process, and may be formed, for example, in a sputtering deposition process.

Referring back to FIG. 3, a first upper electrode TE1 on the first region R1 and a second upper electrode TE2 on the second region R2 may be formed by patterning the upper electrode film TEL. The multiferroic film MFL on the second region R2 may be patterned by using the second upper electrode TE2 as an etching mask, and thus the multiferroic pattern MFP may be formed on the second region R2 of the substrate 100.

The non-magnetic film 164 may be patterned by using the first upper electrode TE1 and the second upper electrode TE2 as etching masks, and thus the first non-magnetic pattern 160 on the first region R1 and the second non-magnetic pattern 162 on the second region R2 may be formed. The free magnetic film FML may be patterned by using the first upper electrode TE1 and the second upper electrode TE2 as the etching masks, and thus the first free magnetic structure FMS1 on the first region R1 and the second free magnetic structure FMS2 on the second region R2 may be formed. The tunnel barrier film TBL may be patterned by using the first upper electrode TE1 and the second upper electrode TE2 as the etching masks, and thus the first tunnel barrier pattern TBP1 on the first region R1 and the second tunnel barrier pattern TBP2 on the second region R2 may be formed.

The fixed magnetic film PML may be patterned by using the first upper electrode TE1 and the second upper electrode TE2 as the etching masks, and thus the first fixed magnetic structure PMS1 on the first region R1 and the second fixed magnetic structure PMS2 on the second region R2 may be formed. An operation of patterning the fixed magnetic film PML may include an operation of sequentially patterning the second magnetic film 144, the exchange coupling film 134, and the first magnetic film 124. The first magnetic pattern 120 on the first region R1 and the third magnetic pattern 122 on the second region R2 may be formed by patterning the first magnetic film 124, and the first exchange coupling pattern 130 on the first region R1 and the second exchange coupling pattern 132 on the second region R2 may be formed by patterning the exchange coupling film 134. The second magnetic pattern 140 on the first region R1 and the fourth magnetic pattern 142 on the second region R2 may be formed by patterning the second magnetic film 144. The first fixed magnetic structure PMS1 may include the first magnetic pattern 120, the second magnetic pattern 140, and the first exchange coupling pattern 130 therebetween, and the second fixed magnetic structure PMS2 may include the third magnetic pattern 122, the fourth magnetic pattern 142, and the second exchange coupling pattern 132 therebetween.

The lower electrode film BEL may be patterned by using the first upper electrode TE1 and the second upper electrode TE2 as the etching masks, and thus the first lower electrode BE1 on the first region R1 and the second lower electrode BE2 on the second region R2 may be formed.

The first fixed magnetic structure PMS1, the first tunnel barrier pattern TBP1, the first free magnetic structure FMS1, and the first non-magnetic pattern 160 may constitute a first magnetic tunnel junction pattern MTJ1. The second fixed magnetic structure PMS2, the second tunnel barrier pattern TBP2, the second free magnetic structure FMS2, the second non-magnetic pattern 162, and the multiferroic pattern MFP may constitute a second magnetic tunnel junction pattern MTJ2.

An upper insulating film 180 may be formed on the lower insulating film 110 on the first and second regions R1 and R2 of the substrate 100. The upper insulating film 180 may cover side surfaces of the first lower electrode BE1, the first magnetic tunnel junction pattern MTJ1, and the first upper electrode TE1 on first region R1, and may cover side surfaces of the second lower electrode BE2, the second magnetic tunnel junction pattern MTJ2, and the second upper electrode TE2 on the second region R2.

Upper lines 190 may be formed on the upper insulating film 180 on the first and second regions R1 and R2 of the substrate 100. The first magnetic tunnel junction pattern MTJ1 may be electrically connected to corresponding one among the upper lines 190 through the first upper electrode TE1, and the second magnetic tunnel junction pattern MTJ2 may be electrically connected to corresponding one among the upper lines 190 through the second upper electrode TE2.

FIG. 10 is a cross-sectional view of a magnetic memory device according to some example embodiments. In order to simplify description, a difference from the magnetic memory device described with reference to FIGS. 1 to 6 will be mainly described.

Referring to FIG. 10, each of the first non-magnetic pattern 160 and the second non-magnetic pattern 162 may have a thickness along the first direction D1. A thickness 162T of the second non-magnetic pattern 162 may be different from a thickness 160T of the first non-magnetic pattern 160. The thickness 162T of the second non-magnetic pattern 162 may be smaller than the thickness 160T of the first non-magnetic pattern 160. Accordingly, ferromagnetic coupling FC between the multiferroic pattern MFP and the second free magnetic structure FMS2 described with reference to FIG. 5 may become stronger, and thus thermal stability of the second free magnetic structure FMS2 may be increased.

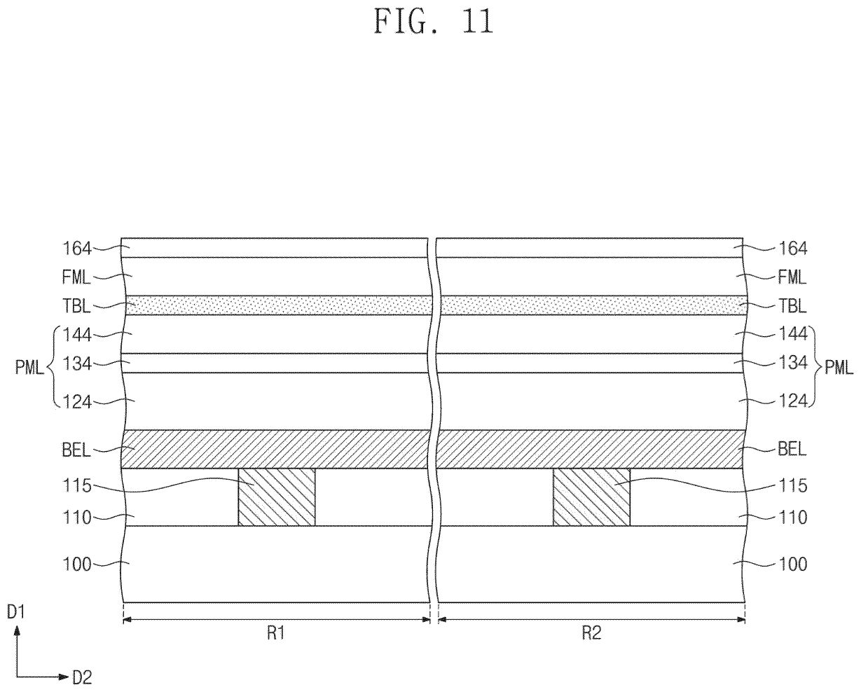

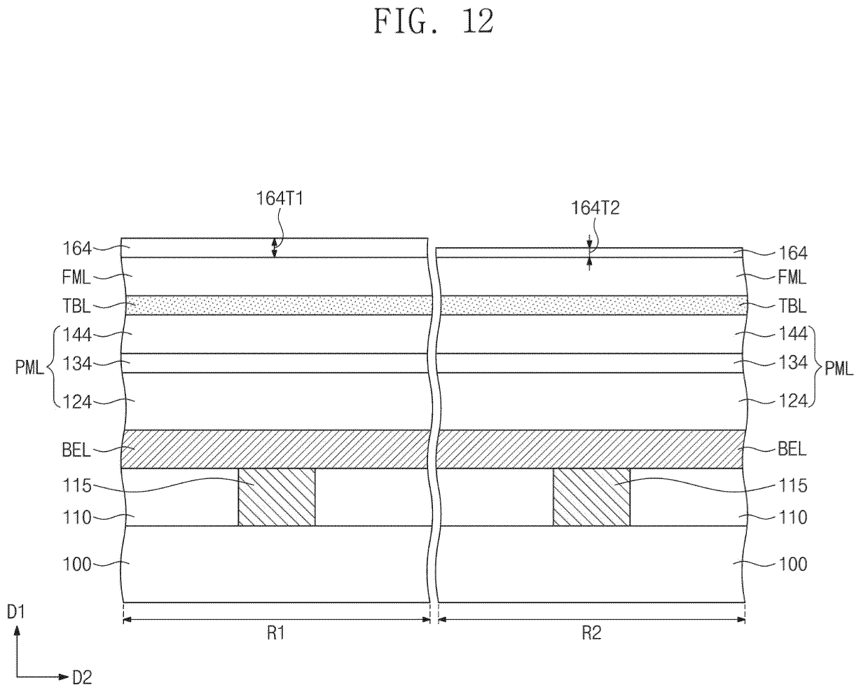

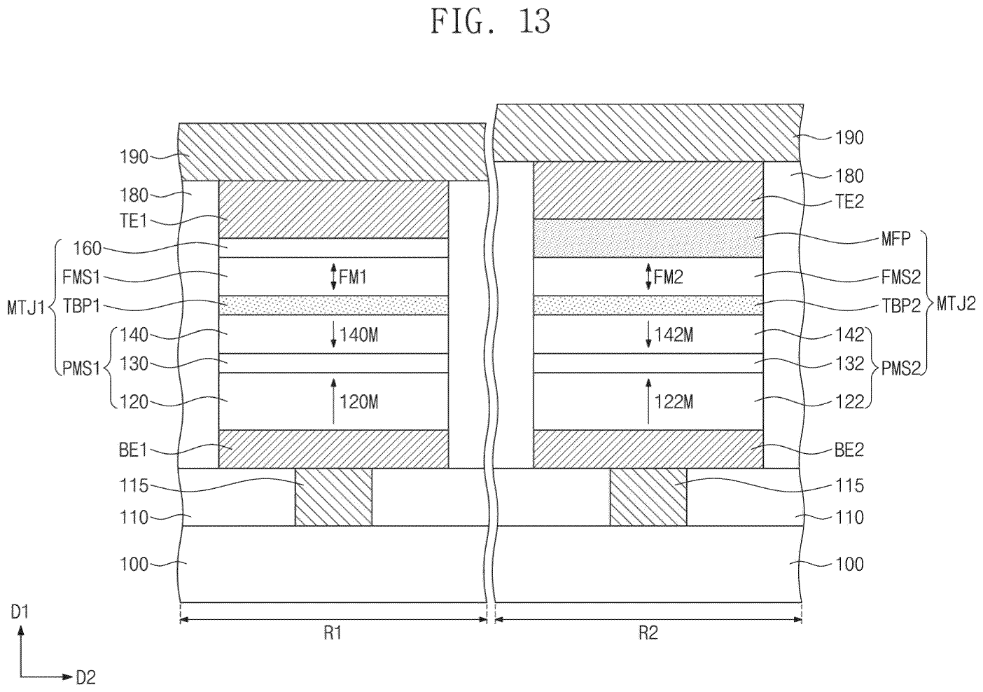

FIGS. 11 and 12 are cross-sectional views illustrating a method for manufacturing a magnetic memory device according to some example embodiments. In order to simplify description, a difference from the method for manufacturing a magnetic memory device described with reference to FIGS. 3, and 7 to 9 will be mainly described.

Referring to FIG. 11, the lower electrode film BEL, the fixed magnetic film PML, the tunnel barrier film TBL, the free magnetic film FML, and the non-magnetic film 164 may be sequentially formed on the first region R1 and the second region R2 of the substrate 100, and on the lower insulating film 110.

Referring to FIG. 12, an upper portion of the non-magnetic film 164 may be recessed on the second region R2 of the substrate 100. For example, recessing the upper portion of the non-magnetic film 164 on the second region R2 may include forming a second mask pattern on the non-magnetic film 164 on the first region R1, performing an etching process to partially etch the upper portion of the non-magnetic film 164 on the second region R2 by using the second mask pattern as an etching mask, and removing the second mask pattern after the etching process. Accordingly, the non-magnetic film 164 may have a first thickness 164T1 on the first region R1, and may have a second thickness 164T2, on the second region R2, smaller than the first thickness 164T1.

Thereafter, as described with reference to FIG. 7, the multiferroic film MFL may be formed on the first region R1 and the second region R2 of the substrate 100, and on the non-magnetic film 164. Processes thereafter are substantially the same as those described with reference to FIGS. 3 and 7 to 9.

FIG. 13 is a cross-sectional view of a magnetic memory device according to some example embodiments. In order to simplify description, a difference from the magnetic memory device described with reference to FIGS. 1 to 6 will be mainly described.

Referring to FIG. 13, according to some example embodiments, the second non-magnetic pattern 162 may be omitted. The first magnetic tunnel junction pattern MTJ1 may include the first fixed magnetic structure PMS1, the first tunnel barrier pattern TBP1, the first free magnetic structure FMS1, and the first non-magnetic pattern 160, and the second magnetic tunnel junction pattern MTJ2 may include the second fixed magnetic structure PMS2, the second tunnel barrier pattern TBP2, the second free magnetic structure FMS2, and the multiferroic pattern MFP. The multiferroic pattern MFP may be in direct contact with the second free magnetic structure FMS2. Accordingly, ferromagnetic coupling FC between the multiferroic pattern MFP and the second free magnetic structure FMS2 described with reference to FIG. 5 may become stronger, and thus thermal stability of the second free magnetic structure FMS2 may be increased.

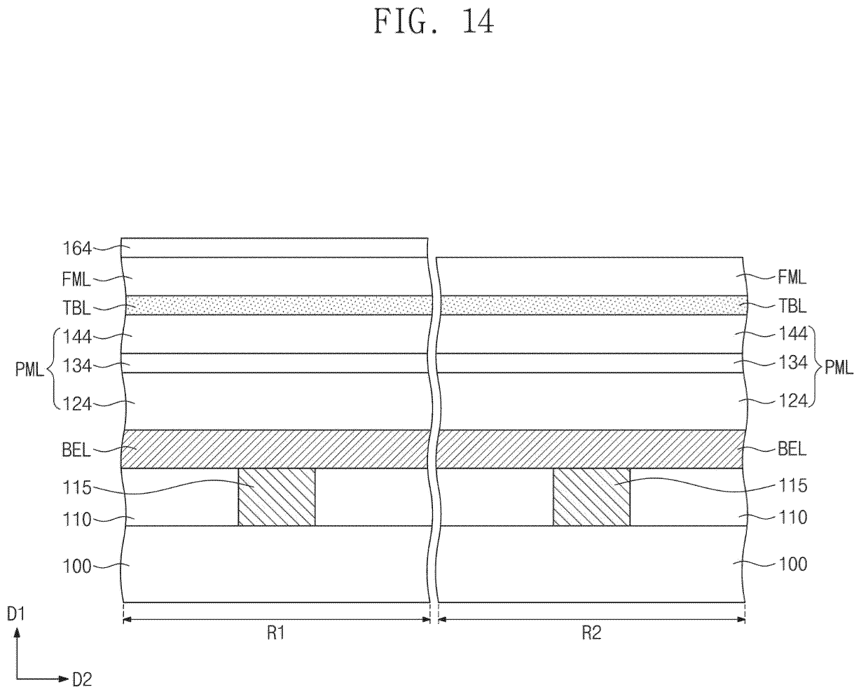

FIG. 14 is a cross-sectional view illustrating a method for manufacturing a magnetic memory device according to some example embodiments. In order to simplify description, a difference from the method for manufacturing a magnetic memory device described with reference to FIGS. 3, and 7 to 9 will be mainly described.

Firstly, as described with reference to FIG. 7, the lower electrode film BEL, the fixed magnetic film PML, the tunnel barrier film TBL, the free magnetic film FML, and the non-magnetic film 164 may be sequentially formed on the first region R1 and the second region R2 of the substrate 100, and on the lower insulating film 110.

Referring to FIG. 14, the non-magnetic film 164 on the second region R2 of the substrate 100 may be selectively removed. For example, an operation of selectively removing the non-magnetic film 164 on the second region R2 may include an operation of forming a second mask pattern on the non-magnetic film 164 on the first region R1, and an operation of etching the non-magnetic film 164 on the second region R2 by using the second mask pattern as an etching mask. The second mask pattern may cover the non-magnetic film 164 on the first region R1, and may expose the non-magnetic film 164 on the second region R2. The operation of etching the non-magnetic film 164 on the second region R2 may be performed until the free magnetic film FML on the second region R2 is exposed. After the non-magnetic film 164 on the second region R2 is selectively removed, the second mask pattern may be removed. For example, the second mask pattern may be a photoresist pattern or hard mask pattern, and may be removed, for example, through an ashing and/or a strip process.

Thereafter, as described with reference to FIG. 7, the multiferroic film MFL may be formed on the first region R1 and the second region R2 of the substrate 100. The multiferroic film MFL may cover the non-magnetic film 164 on the first region R1, and may cover the free magnetic film FML on the second region R2. The multiferroic film MFL may be in direct contact with the free magnetic film FML on the second region R2. Processes thereafter are substantially the same as those described with reference to FIGS. 3 and 7 to 9.

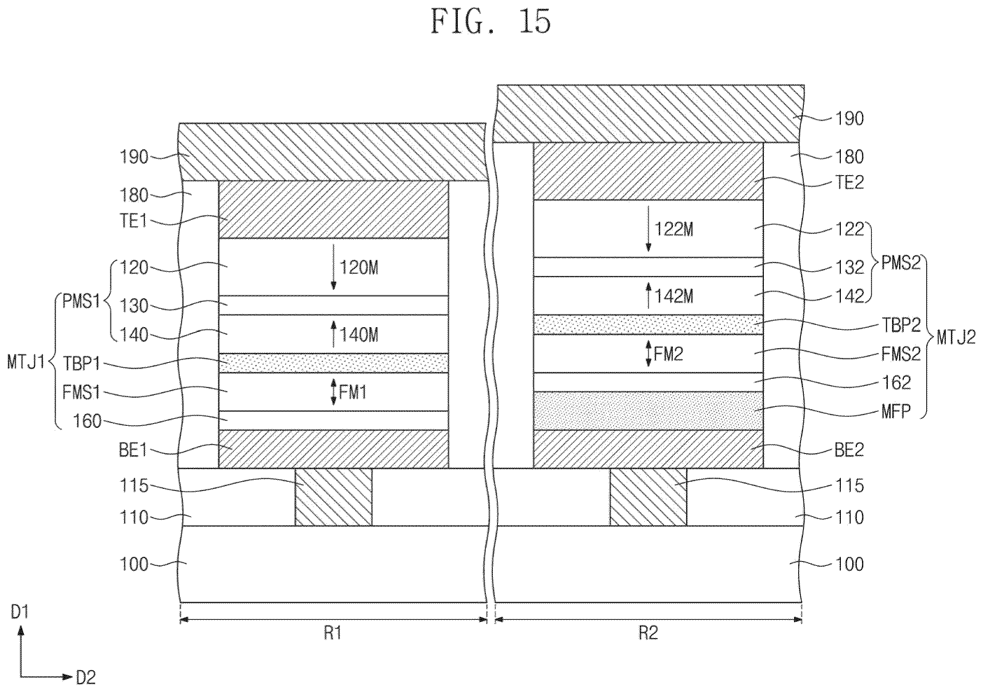

FIG. 15 is a cross-sectional view of a magnetic memory device according to some example embodiments. In order to simplify description, a difference from the magnetic memory device described with reference to FIGS. 1 to 6 will be mainly described.

Referring to FIG. 15, the first magnetic tunnel junction pattern MTJ1 may include the first fixed magnetic structure PMS1, the first free magnetic structure FMS1, the first tunnel barrier pattern TBP1 therebetween, and the first non-magnetic pattern 160. According to some example embodiments, the first free magnetic structure FMS1 may be disposed between the first lower electrode BE1 and the first tunnel barrier pattern TBP1, and the first fixed magnetic structure PMS1 may be disposed between the first tunnel barrier pattern TBP1 and the first upper electrode TE1. The first non-magnetic pattern 160 may be disposed between the first lower electrode BE1 and the first free magnetic structure FMS1.

The first fixed magnetic structure PMS1 may include the first magnetic pattern 120, the second magnetic pattern 140, and the first exchange coupling pattern 130 therebetween. According to some example embodiments, the first magnetic pattern 120 may be disposed between the first upper electrode TE1 and the first exchange coupling pattern 130, and the second magnetic pattern 140 may be disposed between the first exchange coupling pattern 130 and the first tunnel barrier pattern TBP1.

The second magnetic tunnel junction pattern MTJ2 may include the second fixed magnetic structure PMS2, the second free magnetic structure FMS2, the second tunnel barrier pattern TBP2 therebetween, the second non-magnetic pattern 162, and the multiferroic pattern MFP. According to some example embodiments, the second free magnetic structure FMS2 may be disposed between the second lower electrode BE2 and the second tunnel barrier pattern TBP2, and the second fixed magnetic structure PMS2 may be disposed between the second tunnel barrier pattern TBP2 and the second upper electrode TE2. The multiferroic pattern MFP may be disposed between the second lower electrode BE2 and the second free magnetic structure FMS2, and the second non-magnetic pattern 162 may be disposed between the multiferroic pattern MFP and the second free magnetic structure FMS2.

The second fixed magnetic structure PMS2 may include the third magnetic pattern 122, the fourth magnetic pattern 142, and the second exchange coupling pattern 132 therebetween. According to some example embodiments, the third magnetic pattern 122 may be disposed between the second upper electrode TE2 and the second exchange coupling pattern 132, and the fourth magnetic pattern 142 may be disposed between the second exchange coupling pattern 132 and the second tunnel barrier pattern TBP2.

The magnetic memory device described with reference to FIG. 15 is substantially the same as that described with reference to FIGS. 1 to 6, except for the difference described above.

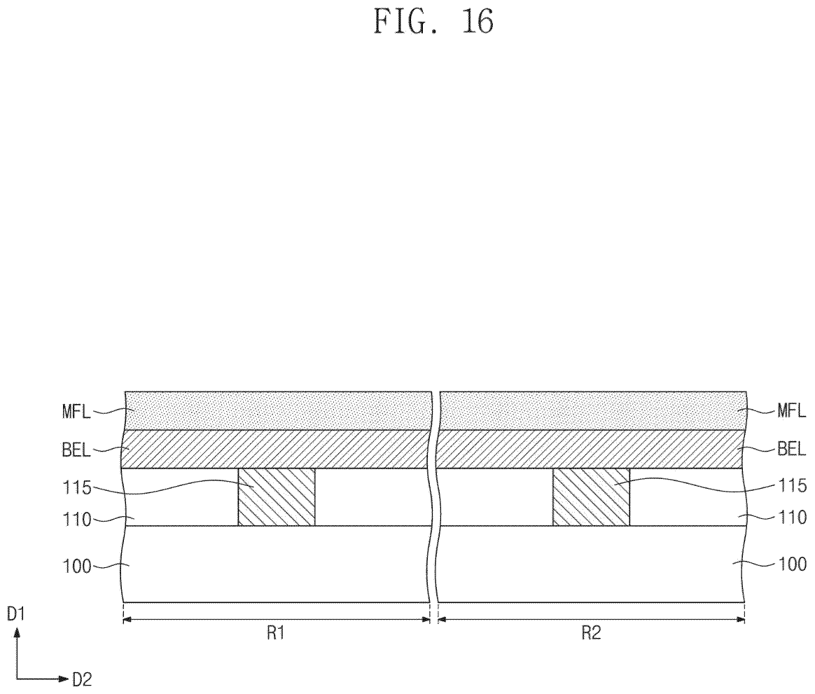

FIGS. 16 to 18 are cross-sectional views illustrating a method for manufacturing a magnetic memory device according to some example embodiments. In order to simplify description, a difference from a method for manufacturing a magnetic memory device described with reference to FIGS. 3 and 7 to 9 will be mainly described.

Referring to FIG. 16, the lower electrode film BEL and the multiferroic film MFL may be formed on the first region R1 and the second region R2 of the substrate 100, and on the lower insulating film 110. The lower electrode film BEL and the multiferroic film MFL may be sequentially stacked on the lower insulating film 110 along the first direction D1.

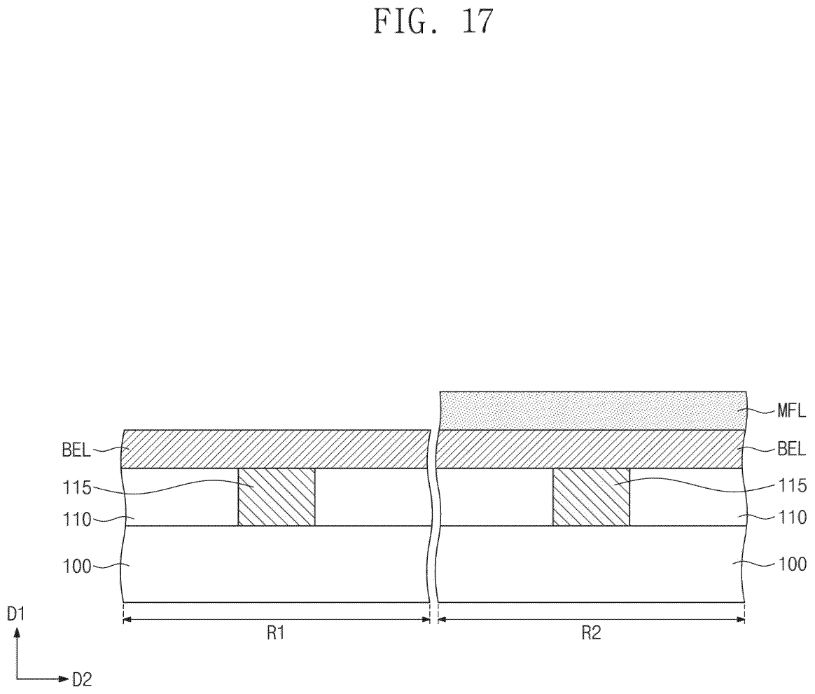

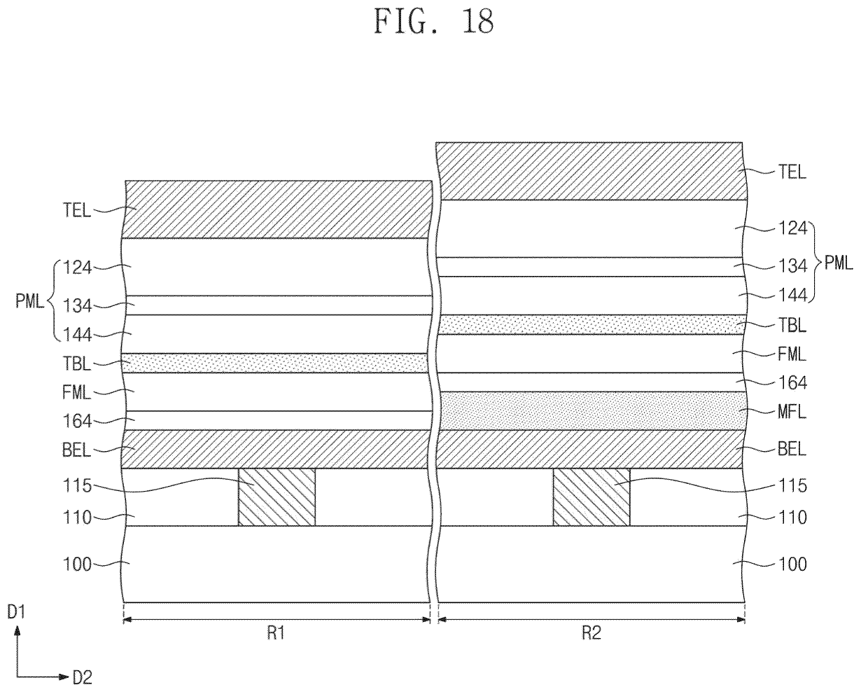

Referring to FIG. 17, the multiferroic film MFL on the first region R1 of the substrate 100 may be selectively removed. An operation of selectively removing the multiferroic film MFL on the first region R1 may be substantially identically performed to the operation described with reference to FIG. 8. Because the multiferroic film MFL on the first region R1 is selectively removed, the lower electrode film BEL on the first region R1 may be exposed.

Referring to FIG. 18, the non-magnetic film 164 may be formed on the first region R1 and the second region R2 of the substrate 100. The non-magnetic film 164 may cover the lower electrode film BEL of the first region R1, and may cover the multiferroic film MFL on the second region R2. The free magnetic film FML, the tunnel barrier film TBL, the fixed magnetic film PML, and the upper electrode film TEL may be formed on the first region R1 and the second region R2 of the substrate 100, and on the non-magnetic film 164. The free magnetic film FML, the tunnel barrier film TBL, the fixed magnetic film PML, and the upper electrode film TEL may be sequentially stacked on the non-magnetic film 164 along the first direction D1. The fixed magnetic film PML may include the first magnetic film 124 adjacent to the upper electrode film TEL, the second magnetic film 144 adjacent to the tunnel barrier film TBL, and the exchange coupling film 134 therebetween.

Referring back to FIG. 15, the first upper electrode TE1 on the first region R1 and the second upper electrode TE2 on the second region R2 may be formed by patterning the upper electrode film TEL. The fixed magnetic film PML may be patterned by using the first upper electrode TE1 and the second upper electrode TE2 as etching masks, and thus the first fixed magnetic structure PMS1 on the first region R1 and the second fixed magnetic structure PMS2 on the second region R2 may be formed. An operation of patterning the fixed magnetic film PML may include an operation of sequentially patterning the first magnetic film 124, the exchange coupling film 134, and the second magnetic film 144. The first magnetic pattern 120 on the first region R1 and the third magnetic pattern 122 on the second region R2 may be formed by patterning the first magnetic film 124, and the first exchange coupling pattern 130 on the first region R1 and the second exchange coupling pattern 132 on the second region R2 may be formed by patterning the exchange coupling film 134. The second magnetic pattern 140 on the first region R1 and the fourth magnetic pattern 142 on the second region R2 may be formed by patterning the second magnetic film 144. The first fixed magnetic structure PMS1 may include the first magnetic pattern 120, the second magnetic pattern 140, and the first exchange coupling pattern 130 therebetween, and the second fixed magnetic structure PMS2 may include the third magnetic pattern 122, the fourth magnetic pattern 142, and the second exchange coupling pattern 132 therebetween.

The tunnel barrier film TBL may be patterned by using the first upper electrode TE1 and the second upper electrode TE2 as etching masks, and thus the first tunnel barrier pattern TBP1 on the first region R1 and the second tunnel barrier pattern TBP2 on the second region R2 may be formed. The free magnetic film FML may be patterned by using the first upper electrode TE1 and the second upper electrode TE2 as etching masks, and thus the first free magnetic structure FMS1 on the first region R1 and the second free magnetic structure FMS2 on the second region R2 may be formed. The non-magnetic film 164 may be patterned by using the first upper electrode TE1 and the second upper electrode TE2 as etching masks, and thus the first non-magnetic pattern 160 on the first region R1 and the second non-magnetic pattern 162 on the second region R2 may be formed. The multiferroic film MFL on the second region R2 may be patterned by using the second upper electrode TE2 as an etching mask, and thus the multiferroic pattern MFP may be formed on the second region R2 of the substrate 100.

The lower electrode film BEL may be patterned by using the first upper electrode TE1 and the second upper electrode TE2 as etching masks, and thus the first lower electrode BE1 on the first region R1 and the second lower electrode BE2 on the second region R2 may be formed.

The first fixed magnetic structure PMS1, the first tunnel barrier pattern TBP1, the first free magnetic structure FMS1, and the first non-magnetic pattern 160 may constitute a first magnetic tunnel junction pattern MTJ1. The second fixed magnetic structure PMS2, the second tunnel barrier pattern TBP2, the second free magnetic structure FMS2, the second non-magnetic pattern 162, and the multiferroic pattern MFP may constitute a second magnetic tunnel junction pattern MTJ2.

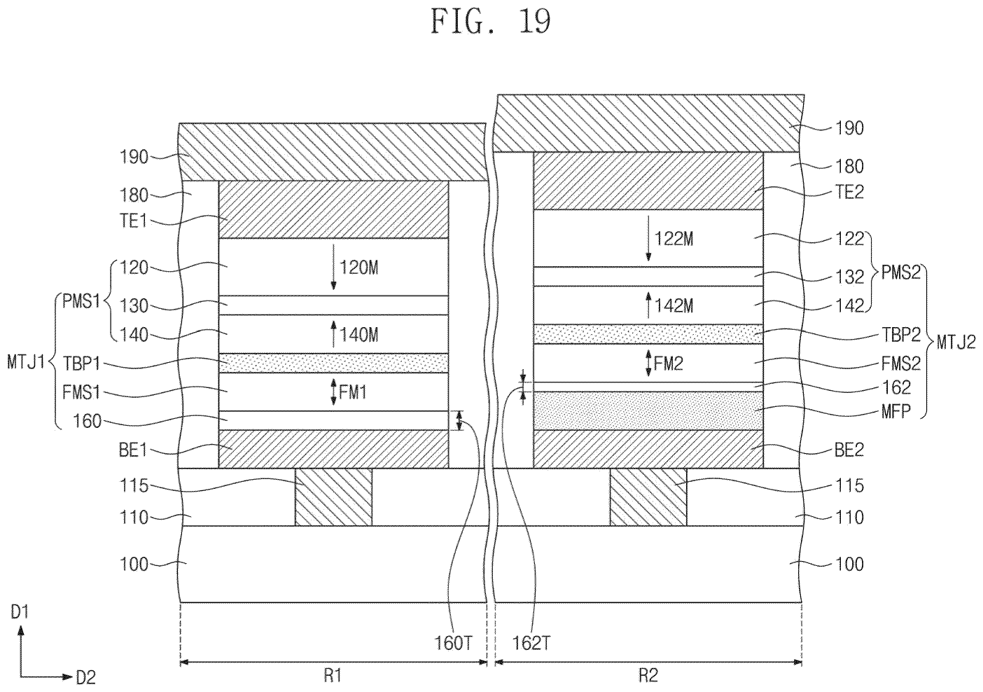

FIG. 19 is a cross-sectional view of a magnetic memory device according to some example embodiments.

Referring to FIG. 19, each of the first non-magnetic pattern 160 and the second non-magnetic pattern 162 may have a thickness along the first direction D1. A thickness 162T of the second non-magnetic pattern 162 may be different from a thickness 160T of the first non-magnetic pattern 160. The thickness 162T of the second non-magnetic pattern 162 may be smaller than the thickness 160T of the first non-magnetic pattern 160. Accordingly, ferromagnetic coupling FC between the multiferroic pattern MFP and the second free magnetic structure FMS2 described with reference to FIG. 5 may become stronger, and thus thermal stability of the second free magnetic structure FMS2 may be increased.

The magnetic memory device described with reference to FIG. 19 is substantially the same as that described with reference to FIG. 15, except for the difference described above.

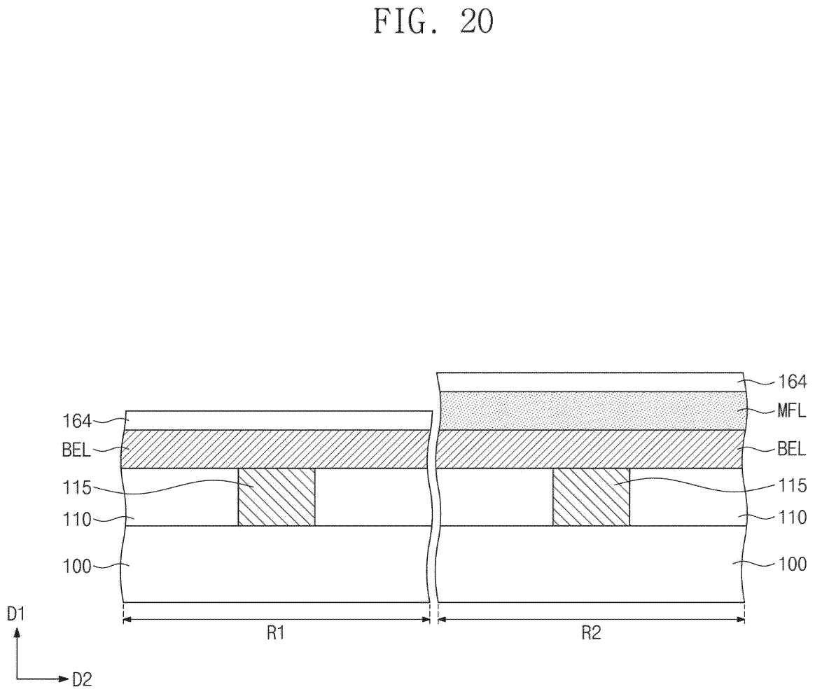

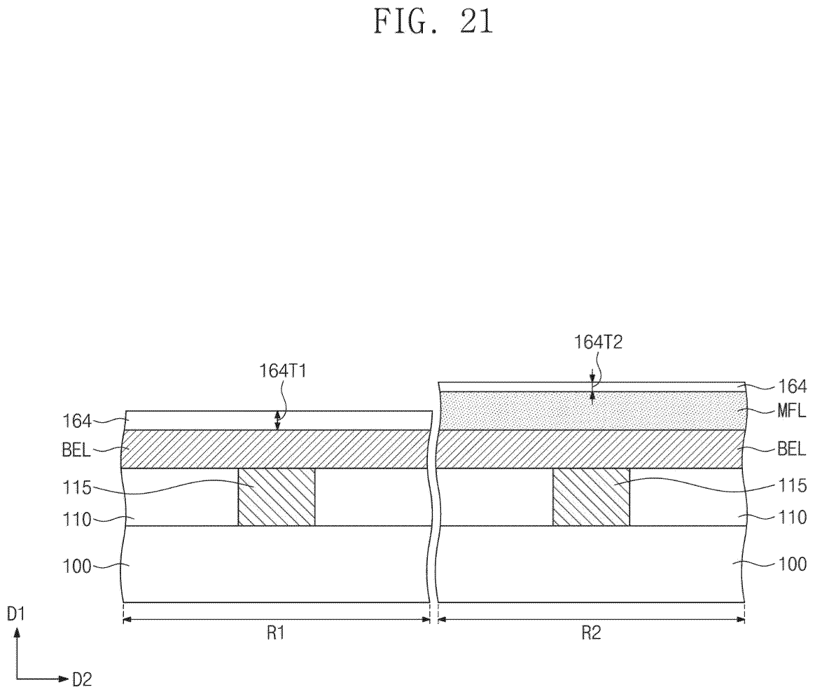

FIGS. 20 and 21 are cross-sectional views illustrating a method for manufacturing a magnetic memory device according to some example embodiments.

Firstly, as described with reference to FIGS. 16 and 17, the lower electrode film BEL and the multiferroic film MFL may be formed on the first region R1 and the second region R2 of the substrate 100, and on the lower insulating film 110, and the multiferroic film MFL on the first region R1 of the substrate 100 may be selectively removed.

Referring to FIG. 20, the non-magnetic film 164 may be formed on the first region R1 and the second region R2 of the substrate 100. The non-magnetic film 164 may cover the lower electrode film BEL of the first region R1, and may cover the multiferroic film MFL on the second region R2.

Referring to FIG. 21, an upper portion of the non-magnetic film 164 on the second region R2 may be recessed. Accordingly, the non-magnetic film 164 may have a first thickness 164T1 on the first region R1, and may have a second thickness 164T2, on the second region R2, smaller than the first thickness 164T1.

Processes thereafter are substantially the same as those described with reference to FIGS. 15 and 18.

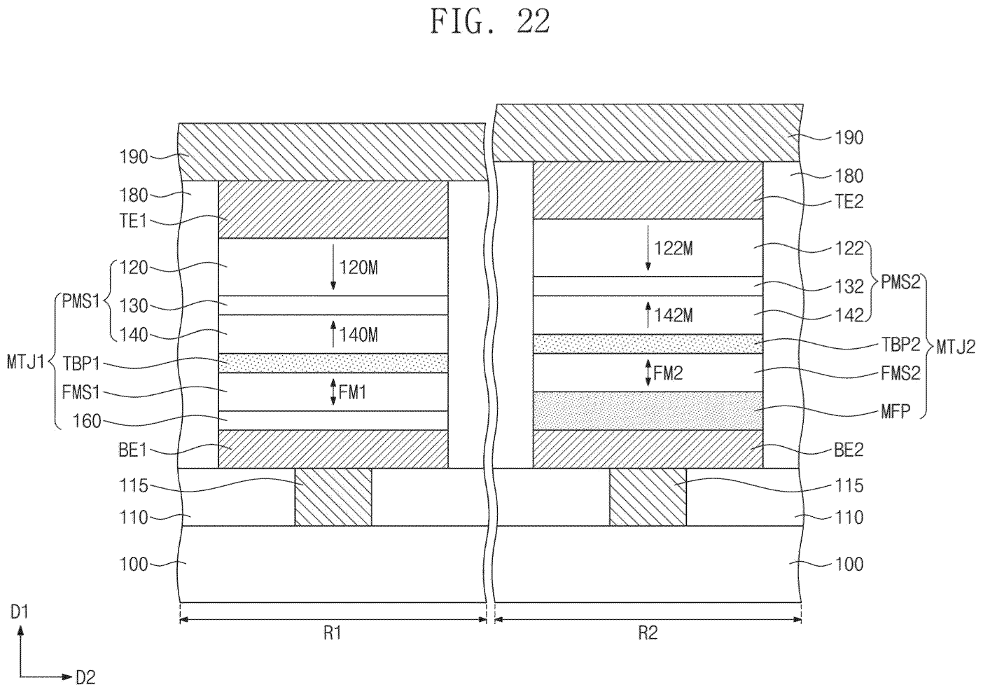

FIG. 22 is a cross-sectional view of a magnetic memory device according to some example embodiments.

Referring to FIG. 22, according to some example embodiments, the second non-magnetic pattern 162 may be omitted. The first magnetic tunnel junction pattern MTJ1 may include the first fixed magnetic structure PMS1, the first tunnel barrier pattern TBP1, the first free magnetic structure FMS1, and the first non-magnetic pattern 160, and the second magnetic tunnel junction pattern MTJ2 may include the second fixed magnetic structure PMS2, the second tunnel barrier pattern TBP2, the second free magnetic structure FMS2, and the multiferroic pattern MFP. The multiferroic pattern MFP may be in direct contact with the second free magnetic structure FMS2. Accordingly, ferromagnetic coupling FC between the multiferroic pattern MFP and the second free magnetic structure FMS2 described with reference to FIG. 5 may become stronger, and thus thermal stability of the second free magnetic structure FMS2 may be increased.

The magnetic memory device described with reference to FIG. 22 is substantially the same as that described with reference to FIG. 15, except for the difference described above.

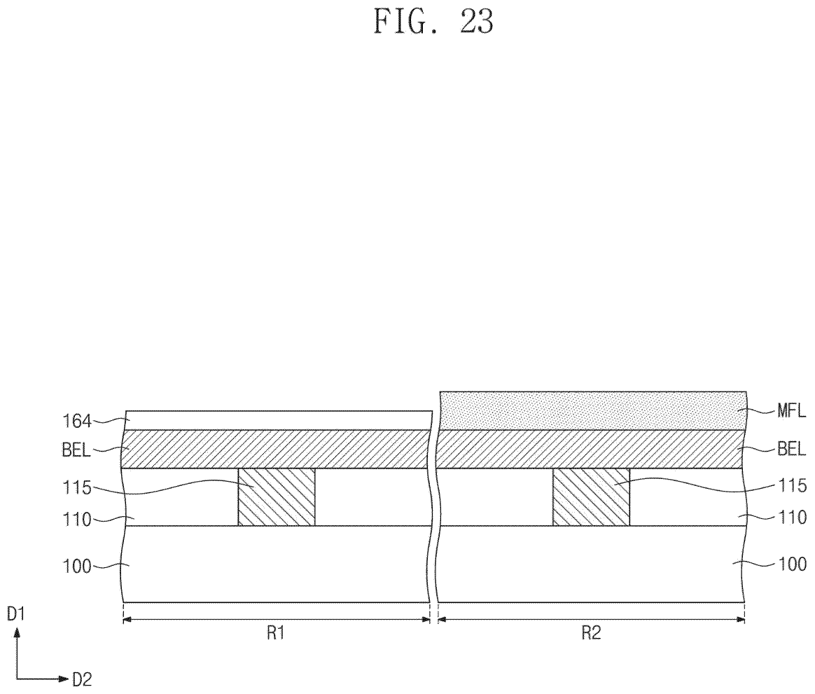

FIG. 23 is a cross-sectional view illustrating a method for manufacturing a magnetic memory device according to some example embodiments.

Firstly, as described with reference to FIGS. 16 to 18, the lower electrode film BEL and the multiferroic film MFL may be formed on the first region R1 and the second region R2 of the substrate 100, and on the lower insulating film 110, and the multiferroic film MFL on the first region R1 of the substrate 100 may be selectively removed. The non-magnetic film 164 may be formed on the first region R1 and the second region R2 of the substrate 100. The non-magnetic film 164 may cover the lower electrode film BEL on the first region R1, and may cover the multiferroic film MFL on the second region R2.

Referring to FIG. 23, the non-magnetic film 164 on the second region R2 of the substrate 100 may be selectively removed. An operation of selectively removing the non-magnetic film 164 on the second region R2 may be substantially identically performed to the operation described with reference to FIG. 14. Because the non-magnetic film 164 on the second region R2 is selectively removed, the multiferroic film MFL on the second region R2 may be exposed.

Thereafter, as described with reference to FIG. 18, the free magnetic film FML may be formed on the first region R1 and the second region R2 of the substrate 100. The free magnetic film FML may cover the non-magnetic film 164 of the first region R1, and may cover the multiferroic film MFL on the second region R2. Processes thereafter are substantially the same as those described with reference to FIGS. 15 and 18.

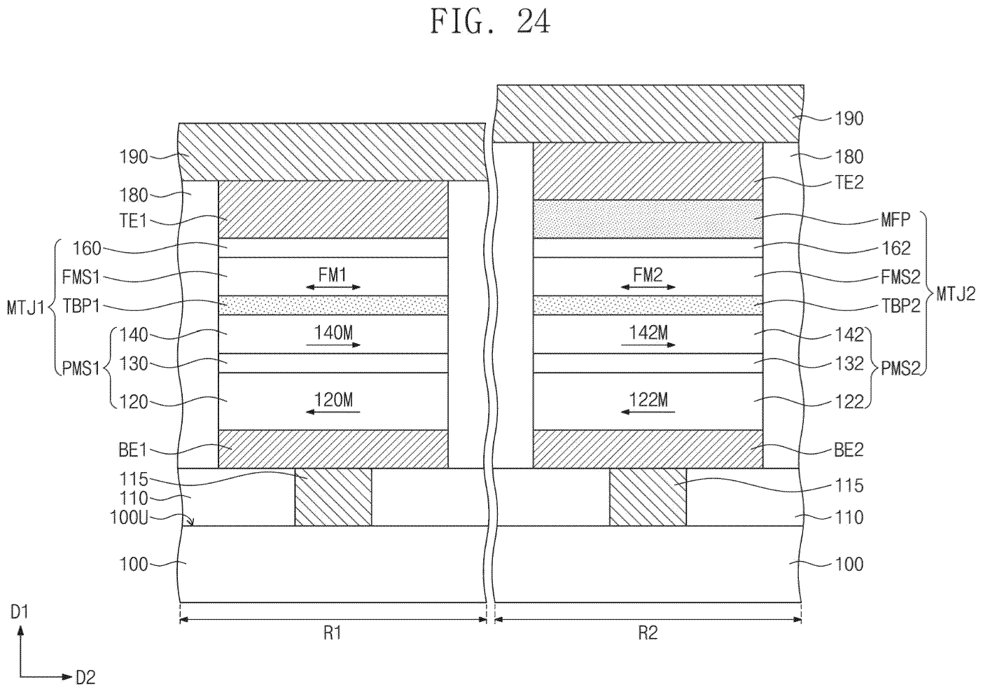

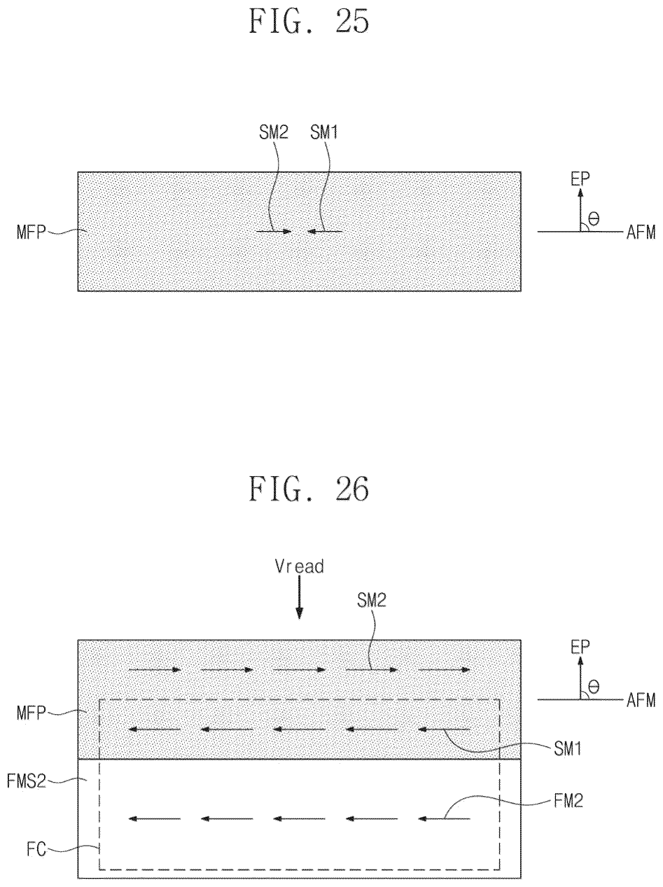

FIG. 24 is a cross-sectional view of a magnetic memory device according to some example embodiments, and FIG. 25 is a conceptual view illustrating characteristics of a multiferroic pattern of FIG. 24. In order to simplify description, a difference from the magnetic memory device described with reference to FIGS. 1 to 6 will be mainly described.

Referring to FIG. 24, the first fixed magnetic structure PMS1 may have in-plane magnetic anisotropy. Magnetization directions 120M and 140M of the first and second magnetic patterns 120 and 140 of the first fixed magnetic structure PMS1 may be parallel to an interface between the first tunnel barrier pattern TBP1 and the first free magnetic structure FMS1 (or an interface between the first tunnel barrier pattern TBP1 and the first fixed magnetic structure PMS1). For example, the magnetization directions 120M and 140M of the first and second magnetic patterns 120 and 140 may be parallel to the upper surface 100U of the substrate 100. Each of the first and second magnetic patterns 120 and 140 may include a ferromagnetic material, and may include, for example, at least one of cobalt-iron-boron (CoFeB), cobalt-iron (CoFe), nickel-iron (NiFe), cobalt-iron-platinum (CoFePt), cobalt-iron-palladium (CoFePd), cobalt-iron-chromium (CoFeCr), cobalt-iron-terbium (CoFeTb), cobalt-iron-nickel (CoFeNi), or the like.

The first free magnetic structure FMS1 may have in-plane magnetic anisotropy. A magnetization direction FM1 of the first free magnetic structure FMS1 may be parallel to an interface between the first tunnel barrier pattern TBP1 and the first free magnetic structure FMS1 (or an interface between the first tunnel barrier pattern TBP1 and the first fixed magnetic structure PMS1). For example, the magnetization direction FM1 of the first free magnetic structure FMS1 may be parallel to the upper surface 100U of the substrate 100. The magnetization direction FM1 of the first free magnetic structure FMS1 may be changed to a direction parallel or antiparallel to the magnetization direction 140M of the second magnetic pattern 140. The first free magnetic structure FMS1 may include a ferromagnetic material including at least one of cobalt (Co), iron (Fe), or nickel (Ni), and may include, for example, CoFeB, CoFe, CoFeNi, and/or the like.

The second fixed magnetic structure PMS2 may have in-plane magnetic anisotropy. Magnetization directions 122M and 142M of the third and fourth magnetic patterns 122 and 142 of the second fixed magnetic structure PMS2 may be parallel to an interface between the second tunnel barrier pattern TBP2 and the second free magnetic structure FMS2 (or an interface between the second tunnel barrier pattern TBP2 and the second fixed magnetic structure PMS2). For example, the magnetization directions 122M and 142M of the third and fourth magnetic patterns 122 and 142 may be parallel to the upper surface 100U of the substrate 100. Each of the third and fourth magnetic patterns 122 and 142 may include a ferromagnetic material, and may include, for example, at least one of cobalt-iron-boron (CoFeB), cobalt-iron (CoFe), nickel-iron (NiFe), cobalt-iron-platinum (CoFePt), cobalt-iron-palladium (CoFePd), cobalt-iron-chromium (CoFeCr), cobalt-iron-terbium (CoFeTb), cobalt-iron-nickel (CoFeNi), or the like.

The second free magnetic structure FMS2 may have in-plane magnetic anisotropy. A magnetization direction FM2 of the second free magnetic structure FMS2 may be parallel to an interface between the second tunnel barrier pattern TBP2 and the second free magnetic structure FMS2 (or an interface between the second tunnel barrier pattern TBP2 and the second fixed magnetic structure PMS2). For example, the magnetization direction FM2 of the second free magnetic structure FMS2 may be parallel to the upper surface 100U of the substrate 100. The magnetization direction FM2 of the second free magnetic structure FMS2 may be changed to a direction parallel or antiparallel to the magnetization direction 142M of the fourth magnetic pattern 142. The second free magnetic structure FMS2 may include a ferromagnetic material including at least one of cobalt (Co), iron (Fe), or nickel (Ni), and may include, for example, CoFeB, CoFe, CoFeNi, and/or the like.

Referring to FIGS. 24 and 25, the multiferroic pattern MFP may have ferroelectricity and antiferromagnetism. The multiferroic pattern MFP may have the first magnetic moment SM1 and second magnetic moment SM2 aligned antiparallel to each other, and may have the antiferromagnetic axis AFM indicating a direction in which the first and second magnetic moments SM1 and SM2 are aligned. A direction of the electric polarization EP of the multiferroic pattern MFP may have a predetermined angle θ with respect to the antiferromagnetic axis AFM. According to some example embodiments, the antiferromagnetic axis AFM of the multiferroic pattern MFP may be parallel to the upper surface 100U of the substrate 100, and the direction of the electric polarization EP of the multiferroic pattern MFP may be perpendicular to the upper surface 100U of the substrate 100.

The magnetic memory device described with reference to FIGS. 24 and 25 is substantially the same as that described with reference to FIGS. 1 to 6, except for the difference described above.

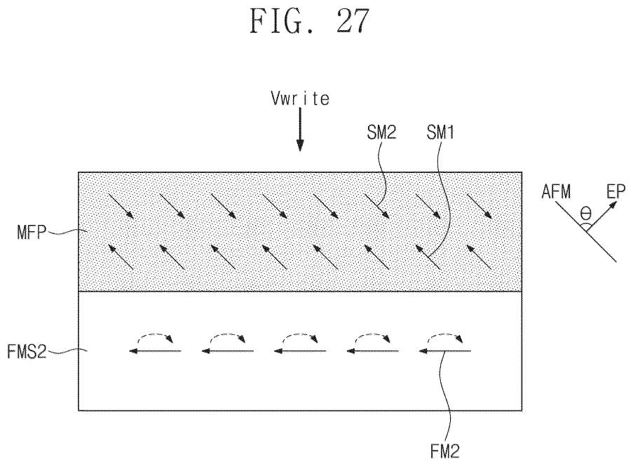

FIG. 26 is a conceptual view partially illustrating the second magnetic tunnel junction pattern of FIG. 24 during a reading operation of a magnetic memory device according to some example embodiments, and FIG. 27 is a conceptual view partially illustrating the second magnetic tunnel junction pattern of FIG. 24 during a writing operation of a magnetic memory device according to some example embodiments. In order to simplify illustration, the second non-magnetic pattern of FIG. 24 is omitted in FIGS. 26 and 27.

Referring to FIG. 26, the first magnetic moment SM1 may be ferromagnetically coupled to the magnetization direction FM2 of the second free magnetic structure FMS2 in a region of the multiferroic pattern MFP, adjacent to the second free magnetic structure FMS2. Because the multiferroic pattern MFP has antiferromagnetism, the second magnetic moment SM2 may be aligned antiparallel to the first magnetic moment SM1. The first and second magnetic moments SM1 and SM2 may be aligned parallel to the antiferromagnetic axis AFM, and the antiferromagnetic axis AFM may be parallel to the magnetization direction FM2 of the second free magnetic structure FMS2. For example, the antiferromagnetic axis AFM of the multiferroic pattern MFP and the magnetization direction FM2 of the second free magnetic structure FMS2 may be parallel to the upper surface 100U of the substrate 100.

A direction of the electric polarization EP of the multiferroic pattern MFP may have the angle θ with respect to the antiferromagnetic axis AFM. For example, when the multiferroic pattern MFP includes BiFeO₃, the direction of the electric polarization EP and the antiferromagnetic axis AFM may be perpendicular to each other. For example, the direction of the electric polarization EP may be perpendicular to the upper surface 100U of the substrate 100.

When a read voltage Vread is applied to the second magnetic tunnel junction pattern MTJ2, a first external electric field caused by the read voltage Vread may be applied to the multiferroic pattern MFP. The read voltage Vread may have a sufficiently small value such that the direction of the electric polarization EP of the multiferroic pattern MFP is not changed by the first external electric field, and may be, for example, equal to or less than about 0.05 V. In this case, the direction of the electric polarization EP of the multiferroic pattern MFP may not be switched by the read voltage Vread, and thus the antiferromagnetic axis AFM of the multiferroic pattern MFP may not be changed by the read voltage Vread.

Due to ferromagnetic coupling FC between the first magnetic moment SM1 of the multiferroic pattern MFP and the magnetization direction FM2 of the second free magnetic structure FMS2, thermal stability of the second free magnetic structure FMS2 may be increased, and the magnetization direction FM2 of the free magnetic structure FMS2 may be prevented from being switched by the read voltage Vread.

Referring to FIG. 27, when a write voltage Vwrite is applied to the second magnetic tunnel junction pattern MTJ2, a second external electric field caused by the write voltage Vwrite may be applied to the multiferroic pattern MFP. The write voltage Vwrite may have a sufficiently large value such that the direction of the electric polarization EP of the multiferroic pattern MFP may be changed by the second external electric field, and may be, for example, greater than about 0.05 V. The write voltage Vwrite may be applied to switch the direction of the electric polarization EP of the multiferroic pattern MFP, and thus the antiferromagnetic axis AFM of the multiferroic pattern MFP may be changed by the write voltage Vwrite.

The antiferromagnetic axis AFM of the multiferroic pattern MFP may be inclined non-parallel to the magnetization direction FM2 of the second free magnetic structure FMS2. For example, the antiferromagnetic axis AFM of the multiferroic pattern MFP may be inclined non-parallel to the upper surface 100U of the substrate 100. The antiferromagnetic axis AFM of the multiferroic pattern MFP may be inclined non-parallel and non-perpendicular to the magnetization direction FM2 of the second free magnetic structure FMS2. For example, the antiferromagnetic axis AFM of the multiferroic pattern MFP may be inclined non-perpendicular and non-parallel to the upper surface 100U of the substrate 100.

Because the antiferromagnetic axis AFM of the multiferroic pattern MFP is inclined non-parallel to the magnetization direction FM2 of the second free magnetic structure FMS2, ferromagnetic coupling FC between the first magnetic moment SM1 of the multiferroic pattern MFP and the magnetization direction FM2 of the second free magnetic structure FMS2 may be reduced. Accordingly, the magnetization direction FM2 of the second free magnetic structure FMS2 may be switched by the write voltage Vwrite.

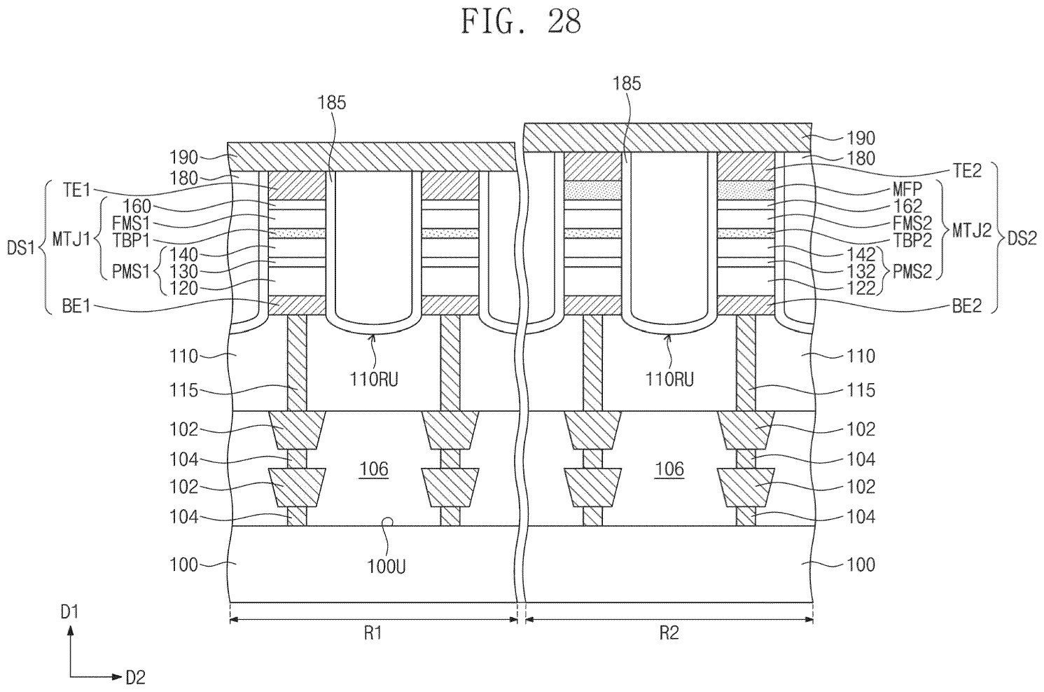

FIG. 28 is a cross-sectional view of a magnetic memory device according to some example embodiments.

Referring to FIG. 28, a substrate 100 including a first region R1 and a second region R2 may be provided. Selective elements SE consistent with the selective element SE shown in FIG. 2 may be disposed on each of the first region R1 and the second region R2 of the substrate 100. For example, a plurality of selective elements SE may be provided in the substrate 100, and each of the lower contact plugs 115 may correspond to one of the selective elements SE in the substrate 100.

Lines 102 and contacts 104 may be disposed on the first region R1 and the second region R2 of the substrate 100. The lines 102 may be spaced apart from an upper surface 100U of the substrate 100 along the first direction D1 perpendicular to the upper surface 100U of the substrate 100. The contacts 104 may be disposed between the lines 102, and between the lowermost lines 102 among the lines 102 and the substrate 100. Each of the lines 102 may be electrically connected to one terminal (for example, a drain terminal) of corresponding one among the selective elements through corresponding one among the contacts 104. The lines 102 and the contacts 104 may include metal (for example, copper).

An interlayer insulating film 106 may be disposed on the first region R1 and the second region R2 of the substrate 100, and may cover the lines 102 and the contacts 104. The interlayer insulating film 106 may expose upper surfaces of the uppermost lines 102 among the lines 102. The upper surfaces of the uppermost lines 102 may be coplanar with an upper surface of the interlayer insulating film 106. The upper surfaces of the uppermost lines 102 may be substantially placed at the same height as the upper surface of the interlayer insulating film 106. In the present specification, a height means a distance measured from the upper surface 100U of the substrate 100 along the first direction D1. For example, the interlayer insulating film 106 may include silicon oxide, silicon nitride, and/or silicon oxynitride.

A lower insulating film 110 may be disposed on the first region R1 and the second region R2 of the substrate 100, and on the interlayer insulating film 106. Lower contact plugs 115 may be disposed on the first region R1 and the second region R2 of the substrate 100, and in the lower insulating film 110. The lower insulating film 110 and the lower contact plugs 115 are substantially the same as the lower insulating film 110 and the lower contact plugs 115 described with reference to FIGS. 1 to 27.

A plurality of first information storage patterns DS1 may be respectively disposed on the lower contact plugs 115 on the first region R1. Each of the first information storage patterns DS1 may include a first lower electrode BE1, a first magnetic tunnel junction pattern MTJ1, and a first upper electrode TE1 sequentially stacked on a corresponding lower contact plug 115. The first lower electrode BE1, the first magnetic tunnel junction pattern MTJ1, and the first upper electrode TE1 may be substantially the same as the first lower electrode BE1, the first magnetic tunnel junction pattern MTJ1, and the first upper electrode TE1 described with reference to FIGS. 1 to 27.

A plurality of second information storage patterns DS2 may be respectively disposed on the lower contact plugs 115 on the second region R2. Each of the second information storage patterns DS2 may include a second lower electrode BE2, a second magnetic tunnel junction pattern MTJ2, and a second upper electrode TE2 sequentially stacked on a corresponding lower contact plug 115. The second lower electrode BE2, the second magnetic tunnel junction pattern MTJ2, and the second upper electrode TE2 may be substantially the same as the second lower electrode BE2, the second magnetic tunnel junction pattern MTJ2, and the second upper electrode TE2 described with reference to FIGS. 1 to 27.

The lower insulating film 110 may have a recessed upper surface 110RU recessed toward the substrate 100 between the first information storage patterns DS1, and between the second information storage patterns DS2.

A protective insulating film 185 may cover a side surface of each of the first and second information storage patterns DS1 and DS2. The protective insulating film 185 may cover side surfaces of the first and second lower electrodes BE1 and BE2, the first and second magnetic tunnel junction patterns MTJ1 and MTJ2, and the first and second upper electrodes TE1 and TE2. The protective insulating film 185 may extend from the side surface of each of the first and second information storage patterns DS1 and DS2 to the recessed upper surface 110RU of the lower insulating film 110. The protective insulating film 185 may conformally extend along the recessed upper surface 110RU of the lower insulating film 110. The protective insulating film 185 may include nitride (for example, silicon nitride).

An upper insulating film 180 may be disposed on the lower insulating film 110 on the first and second regions R1 and R2 of the substrate 100, and may cover the first and second information storage patterns DS1 and DS2. The protective insulating film 185 may be interposed between the side surface of each of the first and second information storage patterns DS1 and DS2 and the upper insulating film 180, and may extend between the recessed upper surface 110RU of the lower insulating film 110 and the upper insulating film 180. For example, the upper insulating film 180 may include silicon oxide, silicon nitride, and/or silicon oxynitride.

Upper lines 190 may be disposed on the upper insulating film 180 on the first and second regions R1 and R2 of the substrate 100. Each of the first information storage patterns DS1 may be connected to corresponding one among the upper lines 190 on the first region R1, and each of the second information storage patterns DS2 may be connected to corresponding one among the upper lines 190 on the second region R2.

According to example embodiments, a first magnetic tunnel junction pattern on a first region of a single substrate may not include a multiferroic pattern, and a second magnetic tunnel junction pattern on a second region of the single substrate may include the multiferroic pattern. Because the multiferroic pattern is selectively provided to the second magnetic tunnel junction pattern, the second magnetic tunnel junction pattern may have higher retention characteristics than the first magnetic tunnel junction pattern, and the first magnetic tunnel junction pattern may have higher switching speed characteristics than the second magnetic tunnel junction pattern. Accordingly, the first magnetic tunnel junction pattern may constitute a first memory cell (for example, a random access memory cell) having relatively high switching speed characteristics, and the second magnetic tunnel junction pattern may constitute a second memory cell (for example, a non-volatile memory cell) having relatively high retention characteristics.

Accordingly, a magnetic memory device including magnetic tunnel junction patterns having different operation characteristics in a single chip may be provided.

While aspects of example embodiments have been particularly shown and described, it will be understood that various changes in form and details may be made therein without departing from the spirit and scope of the following claims.

1. A magnetic memory device comprising:
a substrate;
a first magnetic tunnel junction pattern, on a first region of the substrate, the first magnetic tunnel junction pattern comprising a first fixed magnetic structure, a first free magnetic structure, and a first tunnel barrier pattern between the first fixed magnetic structure and the first free magnetic structure; and
a second magnetic tunnel junction pattern on a second region of the substrate, the second magnetic tunnel junction pattern comprising a second fixed magnetic structure, a second free magnetic structure, a second tunnel barrier pattern, and a multiferroic pattern,
wherein the second tunnel barrier pattern is between the second fixed magnetic structure and the second free magnetic structure,
wherein the second free magnetic structure is between the second tunnel barrier pattern and the multiferroic pattern, and
wherein the multiferroic pattern has ferroelectricity and antiferromagnetism, and is selectively provided to the second magnetic tunnel junction pattern.

2. The magnetic memory device of claim 1, wherein the first magnetic tunnel junction pattern further comprises a first non-magnetic pattern adjacent to the first free magnetic structure, and
wherein the first free magnetic structure is between the first tunnel barrier pattern and the first non-magnetic pattern.

3. The magnetic memory device of claim 2, wherein the second magnetic tunnel junction pattern further comprises a second non-magnetic pattern between the second free magnetic structure and the multiferroic pattern.

4. The magnetic memory device of claim 3, wherein the second non-magnetic pattern is thinner than the first non-magnetic pattern.

5. The magnetic memory device of claim 3, wherein the first fixed magnetic structure and the second fixed magnetic structure comprise a common material,
wherein the first tunnel barrier pattern and the second tunnel barrier pattern comprise a common material,
wherein the first free magnetic structure and the second free magnetic structure comprise a common material, and
wherein the first non-magnetic pattern and the second non-magnetic pattern comprise a common material.

6. The magnetic memory device of claim 2, wherein the second free magnetic structure is in direct contact with the multiferroic pattern.

7. The magnetic memory device of claim 1, wherein the first fixed magnetic structure and the second fixed magnetic structure comprise a common material,
wherein the first tunnel barrier pattern and the second tunnel barrier pattern comprise a common material, and
wherein the first free magnetic structure and the second free magnetic structure comprise a common material.

8. The magnetic memory device of claim 1, wherein the first magnetic tunnel junction pattern and the second magnetic tunnel junction pattern have a common width.

9. The magnetic memory device of claim 1, wherein an antiferromagnetic axis of the multiferroic pattern is parallel to a magnetization direction of the second free magnetic structure.

10. The magnetic memory device of claim 9, wherein each of the first fixed magnetic structure, the first free magnetic structure, the second fixed magnetic structure, and the second free magnetic structure has perpendicular magnetic anisotropy.

11. The magnetic memory device of claim 9, wherein each of the first fixed magnetic structure, the first free magnetic structure, the second fixed magnetic structure, and the second free magnetic structure has in-plane magnetic anisotropy.

12. A magnetic memory device comprising:
a substrate;
a first magnetic tunnel junction pattern and a first electrode on a first region of the substrate; and
a second magnetic tunnel junction pattern and second electrode on a second region of the substrate,
wherein the first magnetic tunnel junction pattern comprises:
a first fixed magnetic structure;
a first tunnel barrier pattern between the first fixed magnetic structure and the first electrode; and
a first free magnetic structure between the first tunnel barrier pattern and the first electrode,
wherein the second magnetic tunnel junction pattern comprises:
a second fixed magnetic structure;
a second tunnel barrier pattern between the second fixed magnetic structure and the second electrode;
a second free magnetic structure between the second tunnel barrier pattern and the second electrode; and
a multiferroic pattern between the second free magnetic structure and the second electrode, and
wherein the multiferroic pattern is offset from the first magnetic tunnel junction pattern.

13. The magnetic memory device of claim 12, wherein the multiferroic pattern has antiferromagnetism, and
wherein an antiferromagnetic axis of the multiferroic pattern is parallel to a magnetization direction of the second free magnetic structure.

14. The magnetic memory device of claim 13, wherein the multiferroic pattern and the second free magnetic structure are ferromagnetically coupled to each other.

15. The magnetic memory device of claim 13, wherein the multiferroic pattern has ferroelectricity.

16. The magnetic memory device of claim 12, wherein the first magnetic tunnel junction pattern further comprises a first non-magnetic pattern between the first free magnetic structure and the first electrode.

17. The magnetic memory device of claim 16, wherein the second magnetic tunnel junction pattern further comprises a second non-magnetic pattern between the second free magnetic structure and the multiferroic pattern.

18-20. (canceled)

21. A magnetic memory device comprising:
a substrate;
a first magnetic tunnel junction pattern, on a first region of the substrate, the first magnetic tunnel junction pattern comprising a first fixed magnetic structure, a first free magnetic structure, and a first tunnel barrier pattern between the first fixed magnetic structure and the first free magnetic structure; and
a second magnetic tunnel junction pattern on a second region of the substrate, the second magnetic tunnel junction pattern comprising a second fixed magnetic structure, a second free magnetic structure, a second tunnel barrier pattern, and a multiferroic pattern,
wherein the second tunnel barrier pattern is between the second fixed magnetic structure and the second free magnetic structure,
wherein the second free magnetic structure is between the second tunnel barrier pattern and the multiferroic pattern, and
wherein the multiferroic pattern has ferroelectricity and antiferromagnetism, and is offset from the first magnetic tunnel junction pattern.

22. The magnetic memory device of claim 21, wherein the first magnetic tunnel junction pattern and the second magnetic tunnel junction pattern have different heights.

23. The magnetic memory device of claim 21, wherein a difference in height between the first magnetic tunnel junction pattern and the second magnetic tunnel junction pattern corresponds to a height of the multiferroic pattern.
